(19) United States
(12) Patent Application Publication
(10) Pub. No.: US 2022/0166191 A1
(43) Pub. Date: May 26, 2022

(54) LIGHT EMITTING ELEMENT AND METHOD FOR MANUFACTURING THE SAME

(71) Applicant: Sony Group Corporation, Tokyo (JP)

(72) Inventors: Masayuki TANAKA, Tokyo (JP); Tatsushi HAMAGUCHI, Tokyo (JP); Rintaro KODA, Tokyo (JP)

(21) Appl. No.: 17/437,088

(22) PCT Filed: Feb. 21, 2020
(86) PCT No.: PCT/JP2020/007033

§ 371 Date: Sep. 8, 2021

(30) Foreign Application Priority Data
Mar. 12, 2019 (JP) 2019-044724

(51) Int. Cl. H01S 5/183; H01S 5/042

(52) U.S. Cl. CPC H01S 5/183; H01S 5/04256

(57) ABSTRACT

A light emitting element includes: a laminated structural body 20 in which a first compound semiconductor layer 21, an active layer 23, and a second compound semiconductor layer 22 are laminated; a first electrode 31 electrically connected to the first compound semiconductor layer 21; and a second electrode 32 and a second light reflecting layer 42 formed on the second compound semiconductor layer 22, in which a protrusion 43 is formed on the first surface side of the first compound semiconductor layer 21, a smoothing layer 44 is formed on at least the protrusion 43, the protrusion 43 and the smoothing layer 44 constitute a concave mirror portion, a first light reflecting layer 41 is formed on at least a part of the smoothing layer 44, and the second light reflecting layer 42 has a flat shape.

### TECHNICAL FIELD

The present disclosure relates to a light emitting element and a method for manufacturing the same, and more particularly to a light emitting element including a surface emitting laser element (VCSEL) and a method for manufacturing the same.

### BACKGROUND ART

In a light emitting element including a surface emitting laser element (VCSEL), in general, laser oscillation occurs by causing resonance of a laser beam between two light reflecting layers (Distributed Bragg Reflector (DBR) layers). Then, in a surface emitting laser element having a laminated structural body in which an n-type compound semiconductor layer, an active layer (light emitting layer) including a compound semiconductor, and a p-type compound semiconductor layer are laminated, in general, a second electrode including a transparent conductive material is formed on the p-type compound semiconductor layer, and a second light reflecting layer including a laminated structure of an insulating material and the like are formed on the second electrode. Furthermore, a first light reflecting layer having laminated structure of an insulating material and the like are formed on the n-type compound semiconductor layer side. Note that, for convenience, an axis line passing through the center of a resonator formed by the two light reflecting layers is set as the Z axis, and a virtual plane orthogonal to the Z axis is referred to as the XY plane.

By the way, in a case where the laminated structural body includes a GaAs-based compound semiconductor, a resonator length L_{OR} is about 1 μm. On the other hand, in a case where the laminated structural body includes a GaN-based compound semiconductor, the resonator length L_{OR} is usually several times or more longer than a wavelength of the laser beam emitted from the surface emitting laser element. That is, the resonator length L_{OR} is considerably longer than 1 μm.

Then, when the resonator length L_{OR} becomes long in this way, diffraction loss increases, so that it is difficult to cause laser oscillation. That is, there is a possibility that the light emitting element functions as an LED instead of functioning as the surface emitting laser element. Here, the “diffraction loss” refers to a phenomenon in which the laser beam reciprocating in the resonator gradually dissipates to the outside of the resonator since the light generally tends to spread due to a diffraction effect. To solve such a problem, as a technology for providing a function as a concave mirror to the light reflecting layer, there are, for example, Japanese Patent Application Laid-Open No. 2006-114753, Japanese Patent Application Laid-Open No. 2000-022277, and International Publication WO 2018/083877 A1.

### CITATION LIST

### Patent Document

Patent Document 1: Japanese Patent Application Laid-Open No. 2006-114753
Patent Document 2: Japanese Patent Application Laid-Open No. 2000-022277
Patent Document 3: International Publication WO 2018/083877 A1

### SUMMARY OF THE INVENTION

### Problems to be Solved by the Invention

By the way, to provide the first light reflecting layer that functions as a concave mirror, it is necessary to form a concave portion on a base. However, when the concave portion is formed on the base, unevenness is often generated on the concave portion. Then, as a result, a problem occurs in which unevenness is generated also on the first light reflecting layer formed on the base, the light is scattered, a threshold value of the light emitting element cannot be lowered, and a decrease in luminous efficiency is caused. Thus, it is extremely important that a surface of the base for forming the first light reflecting layer is smooth. However, the patent publications described above do not mention anything about smoothing the surface of the base for forming the first light reflecting layer that functions as the concave mirror.

Thus, an object of the present disclosure is to provide a light emitting element having a configuration and a structure capable of forming a smooth first light reflecting layer, and a method for manufacturing the same.

### Solutions to Problems

A light emitting element of the present disclosure for achieving the object described above includes:

a laminated structural body in which a first compound semiconductor layer, an active layer, and a second compound semiconductor layer are laminated, the first compound semiconductor layer including a first surface and a second surface facing the first surface, the active layer facing the second surface of the first compound semiconductor layer, the second compound semiconductor layer including a first surface facing the active layer and a second surface facing the first surface;

a first electrode electrically connected to the first compound semiconductor layer; and

a second electrode and a second light reflecting layer formed on the second surface of the second compound semiconductor layer, in which

a protrusion is formed on the first surface's side of the first compound semiconductor layer,

a smoothing layer is formed on at least the protrusion,

the protrusion and the smoothing layer constitute a concave mirror portion,

a first light reflecting layer is formed on at least a part of the smoothing layer, and

the second light reflecting layer has a flat shape.

A method for manufacturing a light emitting element according to a first aspect of the present disclosure for achieving the object described above includes steps of:

forming a laminated structural body in which a first compound semiconductor layer, an active layer, and a second compound semiconductor layer are laminated, the first compound semiconductor layer including a first surface and a second surface facing the first surface, the active layer facing the second surface of the first compound semiconductor layer, the second compound semiconductor layer including a first surface facing the active layer and a second surface facing the first surface; and then,

forming a second electrode and a second light reflecting layer on the second surface of the second compound semiconductor layer; and thereafter,

forming a protrusion on the first surface's side of the first compound semiconductor layer; and then,

forming a smoothing layer on at least the protrusion, and then smoothing a surface of the smoothing layer; and thereafter,

forming a first light reflecting layer on at least a part of the smoothing layer, and forming a first electrode electrically connected to the first compound semiconductor layer, in which

the protrusion and the smoothing layer constitute a concave mirror portion, and

the second light reflecting layer has a flat shape.

A method for manufacturing a light emitting element according to a second aspect of the present disclosure for achieving the object described above includes steps of:

forming a laminated structural body in which a first compound semiconductor layer, an active layer, and a second compound semiconductor layer are laminated, the first compound semiconductor layer including a first surface and a second surface facing the first surface, the active layer facing the second surface of the first compound semiconductor layer, the second compound semiconductor layer including a first surface facing the active layer and a second surface facing the first surface; and then

forming a second electrode and a second light reflecting layer on the second surface of the second compound semiconductor layer; and thereafter,

forming a protrusion on the first surface's side of the first compound semiconductor layer, and then smoothing a surface of the protrusion; and then,

forming a first light reflecting layer on at least a part of the protrusion, and forming a first electrode electrically connected to the first compound semiconductor layer, in which

the protrusion constitutes a concave mirror portion, and

the second light reflecting layer has a flat shape.

### BRIEF DESCRIPTION OF DRAWINGS

FIG. 1 is a schematic partial end view of a light emitting element of Example 1.

FIG. 2 is a schematic partial end view of a substrate and the like for explaining a method for manufacturing the light emitting element of Example 1.

FIG. 3 is, continuing from FIG. 2, a schematic partial end view of the substrate and the like for explaining the method for manufacturing the light emitting element of Example 1.

FIG. 4 is, continuing from FIG. 3, a schematic partial end view of the substrate and the like for explaining the method for manufacturing the light emitting element of Example 1.

FIG. 5 is, continuing from FIG. 4, a schematic partial end view of the substrate and the like for explaining the method for manufacturing the light emitting element of Example 1.

FIG. 6 is, continuing from FIG. 5, a schematic partial end view of the substrate and the like for explaining the method for manufacturing the light emitting element of Example 1.

FIG. 7 is a schematic partial end view of a light emitting element of Example 2.

FIG. 8 is a schematic partial end view of a light emitting element of Example 3.

FIG. 9 is a schematic partial end view of a modification of the light emitting element of Example 3.

FIGS. 10A and 10B are schematic partial end views of a light emitting element of Example 4.

FIG. 11 is a schematic partial end view of a light emitting element of Example 6.

FIGS. 12A and 12B are schematic partial end views of a laminated structural body and the like for explaining a method for manufacturing the light emitting element of Example 6.

(A), (B), and (C) of FIG. 13 are conceptual diagrams illustrating light field intensities of a conventional light emitting element, the light emitting element of Example 6, and a light emitting element of Example 9, respectively.

FIG. 14 is a schematic partial end view of a light emitting element of Example 7.

FIG. 15 is a schematic partial end view of a light emitting element of Example 8.

FIG. 16 is a schematic partial end view of the light emitting element of Example 9.

FIG. 17 is a schematic partial end view in which a main part of the light emitting element of Example 9 illustrated in FIG. 16 is cut out.

FIG. 18 is a schematic partial end view of a light emitting element of Example 10.

FIG. 19 is a diagram in which a schematic partial end view of the light emitting element of Example 10 and two longitudinal modes of a longitudinal mode A and a longitudinal mode B are superimposed on each other.

FIG. 20 is a schematic partial end view of a modification of the light emitting element of Example 1.

FIG. 21 is a schematic partial end view of a modification of the light emitting element of Example 2.

FIG. 22 is a conceptual diagram when a Fabry-Perot resonator is assumed that is sandwiched between two concave mirror portions having the same radius of curvature in a light emitting element of the present disclosure.

FIG. 23 is a graph illustrating a relationship among a value of ω₀, a value of a resonator length L_{OR}, and a value of a radius of curvature R_{DBR} on an inner surface of a first light reflecting layer.

FIG. 24 is a graph illustrating a relationship among the value of ω₀, the value of the resonator length L_{OR}, and the value of the radius of curvature R_{DBR} on the inner surface of the first light reflecting layer.

FIGS. 25A and 25B respectively are a diagram schematically illustrating a condensed state of a laser beam when the value of ω₀ is “positive”, and a diagram schematically illustrating a condensed state of the laser beam when the value of ω₀ is “negative”.

FIGS. 26A and 26B are conceptual diagrams schematically illustrating longitudinal modes existing in a gain spectrum determined by an active layer.

FIG. 27 is a schematic diagram illustrating a crystal structure of a hexagonal nitride semiconductor for explaining a polar plane, a non-polar plane, and a semi-polar plane in a nitride semiconductor crystal.

### MODE FOR CARRYING OUT THE INVENTION

Hereinafter, the present disclosure will be described on the basis of examples with reference to the drawings, but the present disclosure is not limited to the examples, and various numerical values and materials in the examples are exemplifications. Note that, description will be given in the following order.

1. General description related to light emitting element of present disclosure and method for manufacturing light emitting element according to first to second aspects of present disclosure

2. Example 1 (light emitting element of present disclosure and method for manufacturing light emitting element according to first aspect of present disclosure)

3. Example 2 (modification of Example 1)

4. Example 3 (another modification of Example 1)

5. Example 4 (method for manufacturing light emitting element according to second aspect of present disclosure)

6. Example 5 (modifications of Examples 1 to 4, light emitting element having first configuration)

7. Example 6 (modifications of Examples 1 to 5, light emitting element having second configuration A)

8. Example 7 (modification of Example 6, light emitting element having second configuration B)

9. Example 8 (modifications of Examples 6 to 7, light emitting element having second configuration C)

10. Example 9 (modifications of Examples 6 to 8, light emitting element having second configuration D)

11. Example 10 (modification of Examples 1 to 9, light emitting element having third configuration)

12. Example 11 (modification of Example 10)

13. Example 12 (another modification of Example 10)

14. Others

### General Description Related to Light Emitting Element of Present Disclosure and Method for Manufacturing Light Emitting Element According to First to Second Aspects of Present Disclosure

In a light emitting element of the present disclosure and a method for manufacturing a light emitting element according to a first aspect of the present disclosure, a “surface of a smoothing layer” refers to a surface of the smoothing layer forming an interface between the smoothing layer and a first light reflecting layer. Furthermore, in a method for manufacturing a light emitting element according to a second aspect of the present disclosure, a “surface of a protrusion” refers to a surface of the protrusion forming an interface between the protrusion and the first light reflecting layer.

In the light emitting element of the present disclosure, and the light emitting element obtained by the method for manufacturing a light emitting element according to the first aspect of the present disclosure (hereinafter, these light emitting elements may be collectively referred to simply as a “light emitting element and the like according to the first aspect of the present disclosure”), it is preferable that a value of a surface roughness Ra₁ of the smoothing layer at an interface between the smoothing layer and the first light reflecting layer is smaller than a value of a surface roughness Ra₂ of the protrusion at an interface between the protrusion and the smoothing layer. Then, in this case, it is desirable that the value of the surface roughness Ra₁ is less than or equal to 1.0 nm. Furthermore, a light emitting element obtained by the method for manufacturing a light emitting element according to the second aspect of the present disclosure (hereinafter, the light emitting element may be referred to as a “light emitting element and the like according to the second aspect of the present disclosure”), the value of the surface roughness Ra₂ of the protrusion at the interface between the protrusion and the first light reflecting layer is desirably less than or equal to 1.0 nm. Note that, a surface roughness Ra is defined in JIS B-610: 2001. Specifically, the surface roughness Ra can be measured by observation based on an AFM or a cross-sectional TEM.

In the light emitting element and the like according to the first aspect of the present disclosure including the preferable mode described above, a mode can be adopted in which an average thickness T_{C} of the smoothing layer at the top of the protrusion is thinner than an average thickness of the smoothing layer T_{P} at the edge of the protrusion. As the value of T_{P}/T_{C}, although not limited thereto,

0.01≤T_{P}/T_{C}≤0.5

can be exemplified. Furthermore, as a value of T_{C}, 1×10⁻⁸ m to 2×10⁻⁶ m can be exemplified.

Moreover, in the light emitting element and the like according to the first aspect of the present disclosure including various preferable modes described above, a mode can be adopted in which a radius of curvature of the smoothing layer is 1×10⁻⁵ m to 1×10⁻³ m. Furthermore, in the light emitting element and the like according to the second aspect of the present disclosure, a mode can be adopted in which a radius of curvature of the protrusion is 1×10⁻⁵ m to 1×10⁻³ m.

Moreover, in the light emitting element and the like according to the first aspect of the present disclosure including various preferable modes described above, a mode can be adopted in which a material constituting the smoothing layer is at least one material selected from a group consisting of a dielectric material, a spin-on-glass based material, a low melting point glass material, a semiconductor material, and a resin.

Moreover, in the method for manufacturing the light emitting element according to the first aspect of the present disclosure including various preferable modes described above, a mode can be adopted in which smoothing processing on the surface of the smoothing layer is based on a wet etching method, or alternatively, a mode can be adopted in which the smoothing processing on the surface of the smoothing layer is based on a dry etching method. Furthermore, in the method for manufacturing a light emitting element according to the second aspect of the present disclosure, a mode can be adopted in which smoothing processing on the surface of the protrusion is based on a wet etching method, or alternatively, a mode can be adopted in which the smoothing processing on the surface of the protrusion is based on a dry etching method.

In the method for manufacturing a light emitting element according to the first to second aspects of the present disclosure, in a case where the smoothing processing on the surface of the smoothing layer is performed by a wet etching method, examples of the wet etching method include a chemical mechanical polishing method (CMP method) and a dipping method. Then, in this case, although depending on a material constituting the smoothing layer or the protrusion, examples of a polishing liquid and an etching solution include colloidal silica, sodium hydrogen carbonate, tetramethylammonium hydroxide (TMAH), hydrogen fluoride water, pure water, and purified water (deionized water). In a case where the smoothing processing on the surface of the smoothing layer is performed by a dry etching method, examples of the dry etching method include a reactive ion etching method (ME method). Specifically, in a case where the smoothing layer includes, for example, Ta₂O₅, a polishing method using colloidal silica can be adopted, a dipping method using HF can be adopted, and an RIE method using a fluorine-based gas can be adopted.

In the light emitting element and the like according to the first aspect of the present disclosure, examples of the dielectric material constituting the smoothing layer include Ta₂O₅, Nb₂O₅, SiN, AlN, SiO₂, Al₂O₃, HfO₂, TiO₂, and Bi₂O₃. Examples of the spin-on-glass based material include a silicate-based material, a siloxane-based material, a methylsiloxane-based material, and a silazane-based material. Examples of the Low melting point glass material include a glass material containing an oxide of bismuth (Bi), a glass material containing an oxide of barium (Ba), a glass material containing an oxide of tin (Sn), a glass material containing an oxide of phosphorus (P), and a glass material containing an oxide of lead (Pb). Examples of the semiconductor material include GaN, GaAs, and InP. Note that, in a case where the smoothing layer and the protrusion include the semiconductor material, lattice matching between the smoothing layer and the protrusion is not required, so that the type and amount of doping of impurities contained in the semiconductor material constituting the smoothing layer, and the crystal orientation may be different from those of the protrusion, and formation can be made not only by an epitaxial growth method but also by a PVD method such as a sputtering method. Examples of the resin constituting the smoothing layer include an epoxy-based resin, a silicone-based resin, a benzocyclobutene (BCB) resin, a polyimide-based resin, and a novolac resin. The smoothing layer can also have a structure in which layers including these materials are laminated.

In the light emitting element and the like according to the first to second aspects of the present disclosure, the protrusion is formed on a first surface side of a first compound semiconductor layer, but the protrusion may be formed on a substrate, or may be formed on the first compound semiconductor layer. Alternatively, the protrusion may be formed on an exposed surface of the substrate or the first compound semiconductor layer on the basis of another material different from that of the substrate or the first compound semiconductor layer, and in this case, examples of the material constituting the protrusion include a transparent dielectric material such as TiO₂, Ta₂O₅, or SiO₂, a silicone-based resin, and an epoxy-based resin, and the protrusion is formed on a first surface (described later) of the substrate or the exposed surface of the first compound semiconductor layer.

With the light emitting element and the like according to the first to second aspects of the present disclosure including various preferable modes and configurations described above, a surface emitting laser element (vertical cavity surface emitting laser (VCSEL)) that emits a laser beam through the first light reflecting layer can be configured, or alternatively, a surface emitting laser element that emits a laser beam through a second light reflecting layer can also be configured.

In the light emitting element and the like according to the first to second aspects of the present disclosure including various preferable modes described above, a mode can be adopted in which a figure drawn by a surface of the first light reflecting layer in contact with the smoothing layer or the protrusion when the first light reflecting layer is cut by a virtual plane including a laminating direction of a laminated structural body (a virtual plane including the Z axis) (hereinafter, referred to as an “inner surface of the first light reflecting layer” for convenience) is a part of a circle or a part of a parabola. There may be a case where the figure is not strictly a part of a circle, or there may be a case where the figure is not strictly a part of a parabola. That is, a case where the figure is roughly a part of a circle, or a case where the figure is roughly a part of a parabola is also included in that “the figure is a part of a circle or a part of a parabola”. Such a portion (region) of the first light reflecting layer that is a part of a circle or a part of a parabola may be referred to as an “effective region of the first light reflecting layer”. The figure drawn by the inner surface of the first light reflecting layer can be obtained by measuring a shape of the interface (the interface between the smoothing layer and the first light reflecting layer or the interface between the protrusion and the first light reflecting layer) with a measuring instrument and by analyzing obtained data on the basis of a least squares method.

In the light emitting element and the like according to the first to second aspects of the present disclosure, the laminated structural body can include, specifically, a GaN-based compound semiconductor. More specifically, examples of the GaN-based compound semiconductor include GaN, AlGaN, InGaN, and AlInGaN. Moreover, these compound semiconductors may contain a boron (B) atom, a thallium (Tl) atom, an arsenic (As) atom, a phosphorus (P) atom, and an antimony (Sb) atom, if desired. An active layer desirably has a quantum well structure. Specifically, the active layer may have a single quantum well structure (SQW structure), or may have a multiple quantum well structure (MQW structure). The active layer having the quantum well structure has a structure in which at least one well layer and one barrier layer are laminated, and as a combination (of a compound semiconductor constituting the well layer and a compound semiconductor constituting the barrier layer), (In_{y}Ga_{(1-y)}N, GaN), (In_{y}Ga_{(1-y)}N, In_{z}Ga_{(1-z)}N) [where y>z], (In_{y}Ga_{(1-y)}N, AlGaN) can be exemplified.

Alternatively, in the light emitting element and the like according to the first to second aspects of the present disclosure, specifically, the laminated structural body can also include a GaAs-based compound semiconductor, or can also include an InP-based compound semiconductor.

The first compound semiconductor layer can include a first conductive type (for example, n-type) compound semiconductor, and a second compound semiconductor layer can include a second conductive type (for example, p-type) compound semiconductor different from the first conductive type. The first compound semiconductor layer and the second compound semiconductor layer are also referred to as a first clad layer and a second clad layer. It is preferable that a current constriction structure is formed between a second electrode and the second compound semiconductor layer. The first compound semiconductor layer and the second compound semiconductor layer may be a layer having a single structure, a layer having a multilayer structure, or a layer having a superlattice structure. Moreover, the layers can be a layer including a composition gradient layer and a concentration gradient layer.

Furthermore, in the light emitting element and the like according to the first to second aspects of the present disclosure including preferable modes and configurations described above, for materials constituting various compound semiconductor layers located between the active layer and the first light reflecting layer, it is preferable that there is no modulation of a refractive index of greater than or equal to 10% (there is no refractive index difference of greater than or equal to 10% with an average refractive index of the laminated structural body as a reference), and as a result, it is possible to suppress occurrence of disturbance of a light field in a resonator.

To obtain the current constriction structure, a current constriction layer including an insulating material (for example, SiO_{X}, SiN_{X}, AlO_{X}) may be formed between the second electrode and the second compound semiconductor layer, or alternatively, a mesa structure may be formed by etching the second compound semiconductor layer by the RIE method or the like, or alternatively, a current constriction region may be formed by partially oxidizing a part of the laminated second compound semiconductor layer from a lateral direction, or a region having reduced conductivity may be formed by ion implantation of impurities into the second compound semiconductor layer, or these may be combined as appropriate. However, the second electrode needs to be electrically connected to a portion of the second compound semiconductor layer through which a current flows due to current constriction.

In a mode in which the protrusion is formed on the substrate, the laminated structural body is formed on a second surface of the substrate. Here, the second surface of the substrate faces the first surface of the compound semiconductor layer. Then, the protrusion is formed on the first surface of the substrate facing the second surface of the substrate. Examples of the substrate include a conductive substrate, a semiconductor substrate, an insulating substrate, specifically, a GaN substrate, a sapphire substrate, a GaAs substrate, a SiC substrate, an alumina substrate, a ZnS substrate, a ZnO substrate, an AlN substrate, a LiMgO substrate, a LiGaO₂ substrate, a MgAl₂O₄ substrate, an InP substrate, a Si substrate, and one in which a base layer or a buffer layer is formed on a surface (main surface) of these substrates. In a case where the laminated structural body includes the GaN-based compound semiconductor, it is preferable to use the GaN substrate as the substrate since the GaN substrate has a low crystal defect density. It is known that a characteristic of the GaN substrate changes to polarity/non-polarity/semi-polarity depending on a growth surface, but any main surface (second surface) of the GaN substrate can be used for forming the compound semiconductor layer. Furthermore, regarding the main surface of the GaN substrate, depending on a crystal structure (for example, cubic type, hexagonal type, and the like), it is possible to use a crystal orientation plane referred to as a name such as a so-called A-plane, B-plane, C-plane, R-plane, M-plane, N-plane, or S-plane, a plane in which these are caused to be off in a specific direction, or the like. Alternatively, a mode can be adopted in which the substrate includes a GaN substrate having the {20-21} plane that is a semi-polar plane as a main surface (a GaN substrate whose main surface is a surface in which c-plane is tilted by about 75 degrees in the m-axis direction).

Examples of a method for forming various compound semiconductor layers constituting the light emitting element include an organic metal chemical vapor deposition method (Metal Organic-Chemical Vapor Deposition method (MOCVD method), Metal Organic-Vapor Phase Epitaxy method (MOVPE method)) or a Molecular Beam Epitaxy method (MBE method), Hydride Vapor Deposition method (HVPE method) in which halogen contributes to transport or reaction, Atomic Layer Deposition method (ALD method), Migration Enhanced Epitaxy method (MEE method), Plasma assisted Physical vapor Deposition method (PPD method), and the like, but the method is not limited thereto. Here, in a case where the laminated structural body includes the GaN-based compound semiconductor, examples of organic gallium source gas in the MOCVD method include trimethylgallium (TMG) gas and triethylgallium (TEG) gas, and examples of nitrogen source gas include ammonia gas and hydrazine gas. In forming a GaN-based compound semiconductor layer having an n-type conductivity type, for example, it is only required to add silicon (Si) as an n-type impurity (n-type dopant), and in forming a GaN-based compound semiconductor layer having a p-type conductivity type, for example, it is only required to add magnesium (Mg) as a p-type impurity (p-type dopant). In a case where aluminum (Al) or indium (In) is contained as a constituent atom of the GaN-based compound semiconductor layer, it is only required to use trimethylaluminum (TMA) gas as an Al source, and it is only required to use trimethylindium (TMI) gas as an In source. Moreover, it is only required to use monosilane gas (SiH₄ gas) as a Si source, and it is only required to use biscyclopentadienyl magnesium gas, methylcyclopentadienyl magnesium, or biscyclopentadienyl magnesium (Cp₂Mg) as a Mg source. Note that, in addition to Si, examples of the n-type impurity (n-type dopant) include Ge, Se, Sn, C, Te, S, O, Pd, and Po, and in addition to Mg, examples of the p-type impurity (p-type dopant) include Zn, Cd, Be, Ca, Ba, C, Hg, and Sr.

By a wet etching method using alkaline aqueous solution such as sodium hydroxide aqueous solution or potassium hydroxide aqueous solution, ammonia solution+hydrogen peroxide solution, sulfuric acid solution+hydrogen peroxide solution, hydrochloric acid solution+hydrogen peroxide solution, phosphoric acid solution+hydrogen peroxide solution, or the like, a chemical mechanical polishing method (CMP method), a mechanical polishing method, a dry etching method, a lift-off method using a laser, or by a combination thereof, the thickness of the substrate may be reduced, or the substrate may be removed to expose the first surface of the first compound semiconductor layer.

As described above, the laminated structural body can be configured to be formed on the polar plane of the GaN substrate. Alternatively, the laminated structural body can be configured to be formed on a main surface including a semi-polar plane or a non-polar plane (non-polar plane) of the GaN substrate, and in this case, an angle formed by a plane orientation of the main surface and c-axis can be made greater than or equal to 45 degrees and less than or equal to 80 degrees, and moreover, the main surface of the GaN substrate can includes the {20-21} plane. In a hexagonal system, for example, notations of crystal planes exemplified below,

{hkīl}PLANE
{hk̅il}PLANE
are written as the {hk-il} plane and the {h-kil} plane in this specification for convenience.

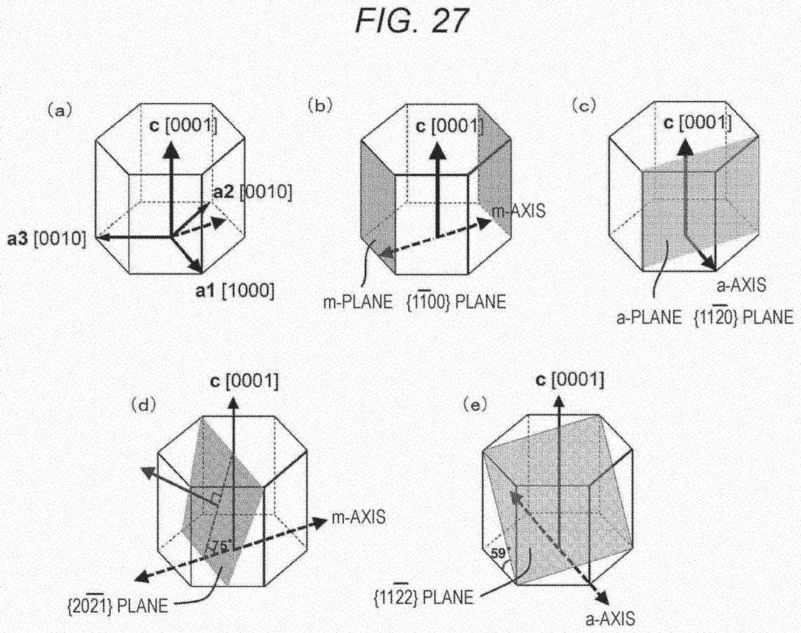

The polar plane, non-polar plane, and semi-polar plane in a nitride semiconductor crystal will be described below with reference to (a) to (e) of FIG. 27. The (a) of FIG. 27 is a schematic diagram illustrating the crystal structure of a hexagonal nitride semiconductor. The (b) of FIG. 27 is a schematic diagram illustrating the m-plane that is a non-polar plane, the {1-100} plane, and the m-plane illustrated by the gray plane is a plane perpendicular to the m-axis direction. The (c) of FIG. 27 is a schematic diagram illustrating the a-plane that is non-polar plane, the {11-20} plane, and the a-plane illustrated by the gray plane is a plane perpendicular to the a-axis direction. The (d) of FIG. 27 is a schematic diagram illustrating the {20-21} plane that is a semi-polar plane. The [20-21] direction perpendicular to the {20-21} plane illustrated by the gray plane is inclined by 75 degrees from the c-axis to the m-axis direction. The (e) of FIG. 27 is a schematic diagram illustrating the {11-22} plane that is a semi-polar plane. The [11-22] direction perpendicular to the {11-22} plane illustrated by the gray plane is inclined by 59 degrees from the c-axis to the a-axis direction. Table 1 below indicates angles formed by plane orientations of various crystal planes and the c-axis. Planes represented by {11-2n} planes such as the {11-21} plane, the {11-22} plane, and the {11-24} plane, the {1-101} plane, the {1-102} plane, and the {1-103} plane are semi-polar planes.

TABLE 1

| PLANE ORIENTATION | ANGLE WITH c AXIS (DEGREES) |
|---|---|
| {1-100} | 90.0 |
| {11-20} | 90.0 |
| {20-21} | 75.1 |
| {11-21} | 72.9 |
| {1-101} | 62.0 |
| {11-22} | 58.4 |
| {1-102} | 43.2 |
| {1-103} | 32.0 |

It is also possible to configure a surface emitting laser element in which the second light reflecting layer is supported by a support substrate and a laser beam is emitted through the first light reflecting layer. The support substrate is only required to include, for example, various substrates exemplified as the substrate described above, or alternatively, can also include an insulating substrate including AlN or the like, a semiconductor substrate including Si, SiC, Ge or the like, or a metal substrate or an alloy substrate, but it is preferable to use a substrate having conductivity, or alternatively, it is preferable to use the metal substrate or the alloy substrate from viewpoints of mechanical properties, elastic deformation, plastic deformation, heat dissipation, and the like. As the thickness of the support substrate, for example, 0.05 mm to 1 mm can be exemplified. As a method for fixing the second light reflecting layer to the support substrate, known methods can be used, such as a solder bonding method, a room temperature bonding method, a bonding method using an adhesive tape, a bonding method using wax bonding, and a method using an adhesive, and it is desirable to adopt the solder bonding method or the room temperature bonding method from a viewpoint of ensuring conductivity. For example, in a case where a silicon semiconductor substrate that is a conductive substrate is used as the support substrate, it is desirable to adopt a method capable of bonding at a low temperature of less than or equal to 400° C. to suppress warpage due to a difference in thermal expansion coefficient. In a case where the GaN substrate is used as the support substrate, the bonding temperature may be greater than or equal to 400° C.

The first compound semiconductor layer is electrically connected to a first electrode. That is, the first electrode is electrically connected to the first compound semiconductor layer via the substrate, or alternatively, the first electrode is formed on the first compound semiconductor layer. Furthermore, the second compound semiconductor layer is electrically connected to the second electrode, and the second light reflecting layer is formed on the second electrode. A mode can be adopted in which the first electrode includes a metal or alloy, and a mode can be adopted in which the second electrode includes a transparent conductive material. By forming the second electrode from the transparent conductive material, the current can be spread in the lateral direction (in-plane direction of the second compound semiconductor layer), and the current can be efficiently supplied to an element region. The second electrode is formed on a second surface of the second compound semiconductor layer. Here, the “element region” refers to a region in which a constricted current is injected, or alternatively, a region in which light is confined due to the refractive index difference and the like, or alternatively, a region in which laser oscillation occurs in a region sandwiched between the first light reflecting layer and the second light reflecting layer, or alternatively, a region that actually contributes to the laser oscillation in the region sandwiched between the first light reflecting layer and the second light reflecting layer.

The first electrode is only required to be formed on the first surface of the substrate facing the second surface of the substrate. The first electrode is desirably have a single layer configuration or a multilayer configuration including at least one metal (including alloy) selected from a group consisting of, for example, gold (Au), silver (Ag), palladium (Pd), platinum (Pt), nickel (Ni), titanium (Ti), vanadium (V), tungsten (W), chromium (Cr), aluminum (Al), copper (Cu), zinc (Zn), tin (Sn), and indium (In), and, specifically, for example, Ti/Au, Ti/Al, Ti/Al/Au, Ti/Pt/Au, Ni/Au, Ni/Au/Pt, Ni/Pt, Pd/Pt, and Ag/Pd can be exemplified. Note that, a layer before “/” in the multilayer configuration is located closer to the active layer side. The same applies to the following description. The first electrode can be formed by a PVD method, for example, a vacuum vapor deposition method, a sputtering method, or the like.

The second electrode can include the transparent conductive material. As the transparent conductive material constituting the second electrode, an indium-based transparent conductive material [specifically, for example, indium-tin oxide (ITO, including Sn-doped In₂O₃, crystalline ITO, and amorphous ITO), Indium-Zinc Oxide (IZO), Indium-Gallium Oxide (IGO), Indium-doped Gallium-Zinc Oxide (IGZO, In—GaZnO₄), IFO (F-doped In₂O₃) ITiO (Ti-doped In₂O₃), InSn, InSnZnO], a tin-based transparent conductive material [specifically, for example, tin oxide (SnO₂), ATO (Sb-doped SnO₂), FTO (F-doped SnO₂)], a zinc-based transparent conductive material [specifically, for example, zinc oxide (ZnO, including Al-doped ZnO (AZO) and B-doped ZnO), gallium-doped zinc oxide (GZO), AlMgZnO (aluminum oxide and magnesium oxide-doped zinc oxide)], and NiO can be exemplified. Alternatively, examples of the second electrode include a transparent conductive film having a gallium oxide, titanium oxide, niobium oxide, antimony oxide, nickel oxide, or the like as a base layer, and also include a transparent conductive material such as a spinel-type oxide and an oxide having a YbFe₂O₄ structure. However, although depending on an arrangement state of the second light reflecting layer and the second electrode, as the material constituting the second electrode, not limited to the transparent conductive material, a metal can also be used, such as palladium (Pd), platinum (Pt), nickel (Ni), gold (Au), cobalt (Co), or rhodium (Rh). The second electrode is only required to include at least one of these materials. The second electrode can be formed by a PVD method, for example, a vacuum vapor deposition method, a sputtering method, or the like. Alternatively, a low-resistance semiconductor layer can also be used as the transparent electrode layer, and in this case, specifically, an n-type GaN-based compound semiconductor layer can also be used. Moreover, in a case where a layer adjacent to the n-type GaN-based compound semiconductor layer is a p-type, electrical resistance at the interface can be reduced by bonding the two layers via a tunnel junction. By forming the second electrode from the transparent conductive material, the current can be spread in the lateral direction (in-plane direction of the second compound semiconductor layer), and the current can be efficiently supplied to a current injection region (described later).

A pad electrode may be provided on the first electrode or the second electrode to electrically connect to an external electrode or circuit. The pad electrode desirably has a single layer configuration or a multilayer configuration including at least one metal selected from a group consisting of titanium (Ti), aluminum (Al), platinum (Pt), gold (Au), nickel (Ni), and palladium (Pd). Alternatively, the pad electrode can also have a multilayer configuration exemplified by a multilayer configuration of Ti/Pt/Au, a multilayer configuration of Ti/Au, a multilayer configuration of Ti/Pd/Au, a multilayer configuration of Ti/Pd/Au, a multilayer configuration of Ti/Ni/Au, or a multilayer configuration of Ti/Ni/Au/Cr/Au. In a case where the first electrode includes an Ag layer or an Ag/Pd layer, it is preferable that a cover metal layer including, for example, Ni/TiW/Pd/TiW/Ni is formed on a surface of the first electrode, and a pad electrode including, for example, a multilayer configuration of Ti/Ni/Au or a multilayer configuration of Ti/Ni/Au/Cr/Au is formed on the cover metal layer.

A light reflecting layer (Distributed Bragg reflector layer (DBR layer)) constituting the first light reflecting layer and the second light reflecting layer includes, for example, a semiconductor multilayer film (for example, AlInGaN film) or a dielectric multilayer film. Examples of a dielectric material include, for example, an oxide of Si, Mg, Al, Hf, Nb, Zr, Sc, Ta, Ga, Zn, Y, B, Ti, or the like, a nitride (for example, SiN_{X}, AlN_{X}, AlGaN_{X}, GaN_{X}, BN_{X}, or the like), fluoride, and the like. Specifically, SiO_{X}, TiO_{X}, NbO_{X}, ZrO_{X}, TaO_{X}, ZnO_{X}, AlO_{X}, HfO_{X}, SiN_{X}, AlN_{X}, and the like can be exemplified. Then, the light reflecting layer can be obtained by alternately laminating two or more kinds of dielectric films including dielectric materials having different refractive indexes among these dielectric materials. For example, dielectric multilayer films are preferable, such as SiO_{X}/SiN_{Y}, SiO_{X}/TaO_{X}, SiO_{X}/NbO_{Y}, SiO_{X}/ZrO_{Y}, and SiO_{X}/AlN_{Y}. To obtain a desired light reflectance, it is only required to appropriately select the material constituting each dielectric film, the film thickness, the number of laminated layers, and the like. The thickness of each dielectric film can be appropriately adjusted depending on the material used and the like, and is determined by an oscillation wavelength (emission wavelength) λ₀ and a refractive index n′ at the oscillation wavelength λ₀ of the material used. Specifically, it is preferable that a value is set of an odd multiple or around the odd multiple of λ₀/(4n′). For example, in a case where the light reflecting layer includes SiO_{X}/NbO_{Y} in a light emitting element having the oscillation wavelength λ₀ of 410 nm, about 40 nm to 70 nm can be exemplified. The number of laminated layers of greater than or equal to 2, preferably about 5 to 20 can be exemplified. As the thickness of the entire light reflecting layer, for example, about 0.6 μm to 1.7 μm can be exemplified. Furthermore, it is desirable that the light reflectance of the light reflecting layer is greater than or equal to 95%.

The light reflecting layer can be formed on the basis of a well-known method, and specifically, examples of the method include: PVD methods such as a vacuum vapor deposition method, a sputtering method, a reactive sputtering method, an ECR plasma sputtering method, a magnetron sputtering method, an ion beam assisted vapor deposition method, an ion plating method, and a laser ablation method; various CVD methods; coating methods such as a spray method, a spin coating method, and a dip method; methods combining two or more of these methods; methods combining these methods with any one kind or more of whole or partial preprocessing, irradiation of inert gas (Ar, He, Xe, or the like) or plasma, irradiation of oxygen gas, ozone gas, and plasma, oxidation processing (heat processing), and exposure processing.

The size and shape of the light reflecting layer are not particularly limited as long as the light reflecting layer covers the current injection region or the element region. As a shape of a boundary between the element region, first light reflecting layer, second light reflecting layer, current injection region and a current non-injection/inner region, a shape of a boundary between the current non-injection/inner region and a current non-injection/outer region, and a planar shape of an opening provided in the element region or the current constriction region, specific examples include a circle, an ellipse, a rectangle, and a polygon (triangle, quadrangle, hexagon, and the like). Furthermore, as a planar shape of the first electrode, an annular shape can be mentioned. The planar shape of the opening provided in the element region, first light reflecting layer, second light reflecting layer, and current constriction layer, a planar shape of an inner ring of the annular first electrode, the shape of the boundary between the current injection region and the current non-injection/inner region, and the shape of the boundary between the current non-injection/inner region and the current non-injection/outer region are desirably similar. In a case where the shape of the boundary between the current injection region and the current non-injection/inner region is circular, the diameter is preferably about 5 μm to 100 μm. The current injection region, the current non-injection/inner region, and the current non-injection/outer region will be described later.

A side surface or an exposed surface of the laminated structural body may be covered with a coating layer (insulating film). Formation of the coating layer (insulating film) can be performed on the basis of a well-known method. A refractive index of a material constituting the coating layer (insulating film) is preferably smaller than a refractive index of a material constituting the laminated structural body. As an insulating material constituting the coating layer (insulating film), a SiO_{X}-based material containing SiO₂, a SiN_{X}-based material, a SiO_{Y}N_{Z}-based material, TaO_{X}, ZrO_{X}, AlN_{X}, AlO_{X}, and GaO_{X} can be exemplified, or alternatively, an organic material such as a polyimide-based resin can also be mentioned. As a method for forming the coating layer (insulating film), for example, a PVD method such as a vacuum vapor deposition method or a sputtering method, or a CVD method can be mentioned, and formation can also be performed on the basis of a coating method.

In the light emitting element and the like according to the first to second aspects of the present disclosure including various preferable modes described above, when the resonator length is L_{OR}, it is preferable that L_{OR}≥1×10⁻⁶ m is satisfied.

### Example 1

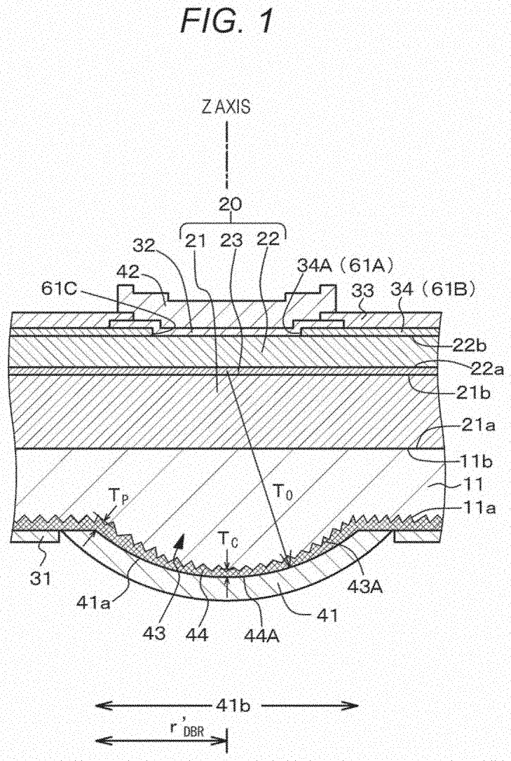

Example 1 relates to the light emitting element of the present disclosure and the method for manufacturing the light emitting element according to the first aspect of the present disclosure. More specifically, a light emitting element of Example 1 or Examples 2 to 12 described later includes a surface emitting laser element (vertical cavity surface emitting laser (VCSEL)) that emits a laser beam from the top surface of the second compound semiconductor layer through the second light reflecting layer. FIG. 1 illustrates a schematic partial end view of the light emitting element of Example 1.

The light emitting element of Example 1 or the light emitting element of Examples 2 to 12 described later includes:

a laminated structural body 20 in which a first compound semiconductor layer 21, an active layer (light emitting layer) 23, and a second compound semiconductor layer 22 are laminated, the first compound semiconductor layer 21 including a first surface 21a and a second surface 21b facing the first surface 21a, the active layer 23 facing the second surface 21b of the first compound semiconductor layer 21, the second compound semiconductor layer 22 including a first surface 22a facing the active layer 23 and a second surface 22b facing the first surface 22a;

a first electrode 31 electrically connected to the first compound semiconductor layer 21; and

a second electrode 32 and a second light reflecting layer 42 formed on the second surface 22b of the second compound semiconductor layer 22.

Then, in the light emitting element of Example 1,

a protrusion 43 is formed on the first surface side of the first compound semiconductor layer 21,

a smoothing layer 44 is formed on at least the protrusion 43,

the protrusion 43 and the smoothing layer 44 constitute a concave mirror portion,

a first light reflecting layer 41 is formed on at least a part of the smoothing layer 44, and

the second light reflecting layer 42 has a flat shape.

Specifically, the protrusion 43 is formed on a first surface 11a of a substrate 11. The laminated structural body 20 is provided on a second surface 11b of the substrate 11. The smoothing layer 44 is formed on the first surface 11a of the substrate including the top of the protrusion 43. The first light reflecting layer 41 is formed on the smoothing layer 44. Here, in Example 1, the substrate 11 includes a compound semiconductor substrate, specifically, a GaN substrate whose main surface is a surface C, the {0001} plane, which is a polar plane. The laminated structural body 20 includes a GaN-based compound semiconductor. The first compound semiconductor layer 21 has a first conductive type (specifically, n-type), and the second compound semiconductor layer 22 has a second conductive type (specifically, p-type) different from the first conductive type. A resonator is configured by a region of the first light reflecting layer 41 from an inner surface 41a of the first light reflecting layer 41 to a certain depth, the smoothing layer 44, the substrate 11 including the protrusion 43, the laminated structural body 20 (the first compound semiconductor layer 21, the active layer 23, and the second compound semiconductor layer 22), the second electrode 32, and a region of the second light reflecting layer 42 from the second surface 22b of the second compound semiconductor layer 22 to a certain depth. Here, when the resonator length is L_{OR}, L_{OR}≥1×10⁻⁶ m (1 μM) is satisfied.

The value of the surface roughness Ra₁ of the smoothing layer 44 at an interface 44A between the smoothing layer 44 and the first light reflecting layer 41 is smaller than the value of the surface roughness Ra₂ of the protrusion 43 at an interface 43A between the protrusion 43 and the smoothing layer 44. The value of the surface roughness Ra₁ is less than or equal to 1.0 nm. Moreover, the average thickness T_{C} of the smoothing layer 44 at the top of the protrusion 43 is thinner than the average thickness of the smoothing layer 44 T_{P} at the edge of the protrusion 43. Specifically, the value of T_{P}/T_{C} satisfies

0.01≤T_{P}/T_{C}≤0.5

and, the value of the T_{C} satisfies 1×10⁻⁸ m to 2×10⁻⁶ m, and more specifically,

T_{C}=0.2 μm

T_{P}/T_{C}=0.05.

The radius of curvature of the smoothing layer 44 is 1×10⁻⁵ m to 1×10⁻³ m, and specifically is 100 μm.

A material constituting the smoothing layer 44 is at least one material selected from a group consisting of a dielectric material, a spin-on-glass based material, a low melting point glass material, a semiconductor material, and a resin. In Example 1, specifically, as the material constituting the smoothing layer 44, for example, a dielectric material, more specifically, Ta₂O₅ was used.

Then, in the light emitting element of Example 1, a figure drawn by the inner surface 41a of the first light reflecting layer 41 (an effective region 41b of the first light reflecting layer 41) when the first light reflecting layer 41 is cut by a virtual plane including the laminating direction of the laminated structural body 20 (the virtual plane including the Z axis) is a part of a circle or a part of a parabola. However, a shape of the first light reflecting layer 41 (a figure of a cross-sectional shape) located outside the effective region 41b does not have to be a part of a circle or a part of a parabola. The first light reflecting layer 41 extends above a part of the first surface 11a of the substrate 11, and a shape (figure of a cross-sectional shape) of this portion is flat. The first light reflecting layer 41 and the second light reflecting layer 42 include a multilayer light reflecting film. A planar shape of the outer edge of the protrusion 43 is circular.

Moreover, when a radius of the effective region 41b of the first light reflecting layer 41 is r′_{DBR} and a radius of curvature is R_{DBR},

R_{DBR}≤1×10⁻³ m

is satisfied. Specifically, although not limited thereto,

L_{OR}=50 μm

R_{DBR}=70 μm

r′_{DBR}=25 μm

can be exemplified. Furthermore, as the oscillation wavelength λ₀ of main light emitted from the active layer 23,

λ₀=445 nm

can be exemplified.

Here, when a distance from an area center of gravity of the active layer 23 to the inner surface 41a of the first light reflecting layer 41 is T₀, and when a length of a portion of a resonator including the inner surface 41a of the first light reflecting layer 41 and the first surface 21a of the first compound semiconductor layer 21 is L_{DBR}, an ideal parabolic function x=f(z) can be represented by

x=z²/t₀

L_{DBR}=r′_{DBR}²/2T₀;

however, it goes without saying that when the figure drawn by the inner surface 41a is a part of the parabola, the parabola may deviate from such an ideal parabola.

A value of thermal conductivity of the laminated structural body 20 is higher than a value of thermal conductivity of the first light reflecting layer 41. A value of thermal conductivity of the dielectric material constituting the first light reflecting layer 41 is generally about 10 watts/(m·K), or equal to or less than that. On the other hand, a value of thermal conductivity of the GaN-based compound semiconductor constituting the laminated structural body 20 is about 50 watts/(m·K) to about 100 watts/(m·K).

The first compound semiconductor layer 21 includes an n-GaN layer; the active layer 23 includes a five-layered multiple quantum well structure in which an In_{0.04}Ga_{0.96}N layer (barrier layer) and an In_{0.16}Ga_{0.84}N layer (well layer) are laminated; and the second compound semiconductor layer 22 includes a p-GaN layer. The first electrode 31 is formed on the first surface 11a of the substrate 11, and is electrically connected to the first compound semiconductor layer 21 via the substrate 11. On the other hand, the second electrode 32 is formed on the second compound semiconductor layer 22, and the second light reflecting layer 42 is formed on the second electrode 32. The second light reflecting layer 42 on the second electrode 32 has a flat shape. The first electrode 31 includes Ti/Pt/Au, and the second electrode 32 includes a transparent conductive material, specifically, ITO. On the edge of the first electrode 31, a pad electrode (not illustrated) including, for example, Ti/Pt/Au or V/Pt/Au for electrically connecting to an external electrode or circuit is formed or connected. On the edge of the second electrode 32, a pad electrode 33 including, for example, Pd/Ti/Pt/Au, Ti/Pd/Au, or Ti/Ni/Au for electrically connecting to an external electrode or circuit is formed or connected. The first light reflecting layer 41 and the second light reflecting layer 42 include a laminated structure of a Ta₂O₅ layer and a SiO₂ layer (total number of laminated layers of dielectric films: 20 layers). Although the first light reflecting layer 41 and the second light reflecting layer 42 have a multilayer structure as described above, they are represented by one layer for simplification of the drawing. A planar shape of each of the first electrode 31, the first light reflecting layer 41, the second light reflecting layer 42, and an opening 34A provided in an insulating layer (current constriction layer) 34 is circular. As will be described later, the current constriction region (a current injection region 61A and a current non-injection region 61B) is defined by the insulating layer 34 including the opening 34A, and the current injection region 61A is defined by the opening 34A.

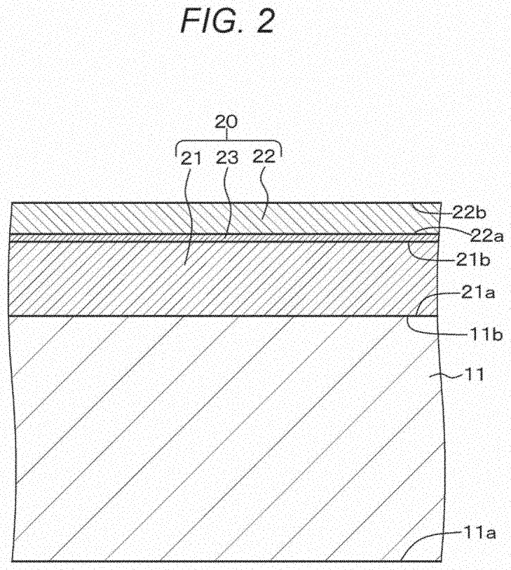

Hereinafter, a method for manufacturing the light emitting element of Example 1 will be described with reference to FIGS. 2, 3, 4, 5, and 6.

### [Step-100]

First, on a surface (the second surface 11b) of the substrate 11, the laminated structural body 20 is formed in which the first compound semiconductor layer 21, the active layer 23, and the second compound semiconductor layer 22 are laminated, the first compound semiconductor layer 21 including the first surface 21a and the second surface 21b facing the first surface 21a, the active layer 23 facing the second surface 21b of the first compound semiconductor layer 21, the second compound semiconductor layer 22 including the first surface 22a facing the active layer 23 and the second surface 22b facing the first surface 22a. Specifically, on the basis of the MOCVD method, the first compound semiconductor layer 21, the active layer 23, and the second compound semiconductor layer 22 including n-GaN are formed on the second surface 11b of the exposed substrate 11, whereby the laminated structural body 20 can be obtained (see FIG. 2).

### [Step-110]

Next, on the basis of a combination of a film forming method such as a CVD method, a sputtering method, or a vacuum vapor deposition method and a wet etching method or a dry etching method, the insulating layer (current constriction layer) 34 including the opening 34A and including SiO₂ is formed on the second surface 22b of the second compound semiconductor layer 22. The current constriction region (the current injection region 61A and the current non-injection region 61B) are defined by the insulating layer 34 including the opening 34A. That is, the current injection region 61A is defined by the opening 34A.

To obtain the current constriction region, an insulating layer (current constriction layer) including an insulating material (for example, SiO_{X}, SiN_{X}, AlO_{X}) may be formed between the second electrode 32 and the second compound semiconductor layer 22, or alternatively, a mesa structure may be formed by etching the second compound semiconductor layer 22 by the RIE method or the like, or alternatively, a current constriction region may be formed by partially oxidizing a part of the laminated second compound semiconductor layer 22 from a lateral direction, or a region having reduced conductivity may be formed by ion implantation of impurities into the second compound semiconductor layer 22, or these may be combined as appropriate. However, the second electrode 32 needs to be electrically connected to the portion of the second compound semiconductor layer 22 through which the current flows due to the current constriction.

### [Step-120]

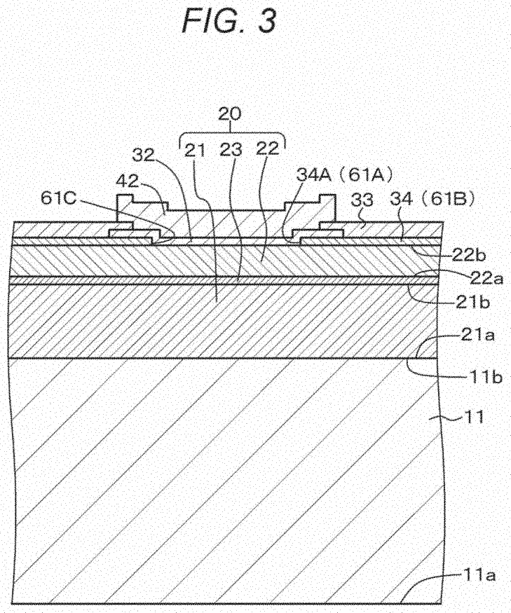

Thereafter, the second electrode 32 and the second light reflecting layer 42 are formed on the second surface of the second compound semiconductor layer 22. Specifically, the second electrode 32 is formed over the insulating layer 34 from the second surface 22b of the second compound semiconductor layer 22 exposed on the bottom surface of the opening 34A (current injection region 61A) on the basis of the lift-off method, for example, and moreover, the pad electrode 33 is formed on the basis of a combination of a film forming method such as a sputtering method or a vacuum vapor deposition method and a patterning method such as a wet etching method or a dry etching method. Next, the second light reflecting layer 42 is formed over the pad electrode 33 from the second electrode 32 on the basis of a combination of a film forming method such as a sputtering method or a vacuum vapor deposition method and a patterning method such as a wet etching method or a dry etching method (see FIG. 3). The second light reflecting layer 42 on the second electrode 32 has a flat shape.

### [Step-130]

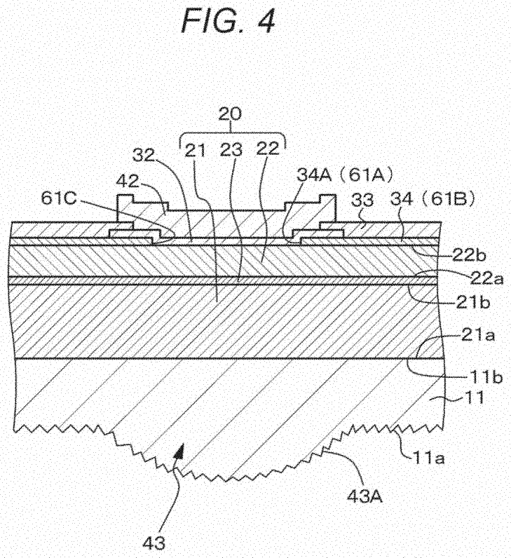

Next, the protrusion 43 is formed on the first surface side of the first compound semiconductor layer 21. Specifically, first, the substrate 11 is thinned from the first surface 11a side to a desired thickness. Then, a resist layer is formed on the first surface 11a of the substrate 11, and the resist layer is patterned to leave the resist layer on the substrate 11 on which the protrusion 43 is to be formed. Then, heat processing is performed on the resist layer to form a protrusion in the resist layer. Next, the resist layer and the substrate 11 are etched back on the basis of the RIE method. In this way, as illustrated in FIG. 4, the protrusion 43 can be formed on the first surface 11a of the substrate 11. An outer shape of the protrusion 43 is circular.

### [Step-140]

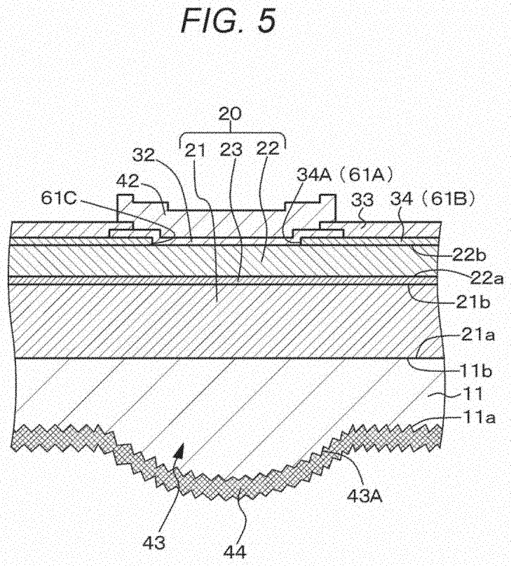

Thereafter, the smoothing layer 44 is formed on at least the protrusion 43 (see FIG. 5). Specifically, the smoothing layer 44 is formed on the entire surface of the first surface 11a of the substrate 11 including the protrusion 43 on the basis of the sputtering method.

### [Step-150]

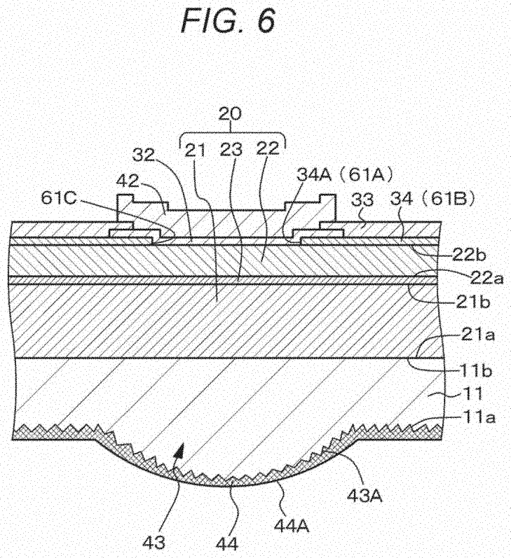

Next, a surface of the smoothing layer 44 is smoothed (see FIG. 6). Specifically, smoothing processing on the surface of the smoothing layer 44 is performed on the basis of the wet etching method. More specifically, the smoothing processing on the surface of the smoothing layer 44 is performed on the basis of the CMP method using colloidal silica as the polishing liquid. The surface roughness of the surface of the smoothing layer 44 was as follows before and after the smoothing processing.

Before smoothing processing: Ra=0.36 nm

After smoothing processing: Ra₁=0.14 nm

### [Step-160]

Thereafter, the first light reflecting layer 41 is formed on at least a part of the smoothing layer 44, and the first electrode 31 electrically connected to the first compound semiconductor layer 21 is formed. Specifically, the first light reflecting layer 41 including a dielectric multilayer film is formed on the smoothing layer 44 on the basis of a combination of a film forming method such as a sputtering method or a vacuum vapor deposition method and a patterning method such as a wet etching method or a dry etching method. A planar shape of the outer edge of the first light reflecting layer 41 left on the first surface 11a of the substrate 11 is circular. Thereafter, the first electrode 31 is formed on the first surface 11a of the substrate 11 on the basis of a combination of a film forming method such as a sputtering method or a vacuum vapor deposition method and a patterning method such as a wet etching method or a dry etching method. In this way, a structure illustrated in FIG. 1 can be obtained. Then, moreover, the light emitting element is separated by performing so-called element separation, and the side surface and the exposed surface of the laminated structural body 20 are covered with a coating layer (not illustrated) including, for example, an insulating material such as SiO₂. Then, the light emitting element of Example 1 can be completed by packaging or sealing.

In the light emitting element of Example 1 or a light emitting element obtained by the method for manufacturing the light emitting element of Example 1, the surface of the smoothing layer that is a base of the first light reflecting layer is smooth, so that the first light reflecting layer formed on the smoothing layer is also smooth. Thus, as a result of being able to suppress scattering of light by the first light reflecting layer, it is possible to lower a threshold value of the light emitting element and improve luminous efficiency.

Moreover, in the light emitting element of Example 1, since the first light reflecting layer is formed above the protrusion, light is diffracted and spread with the active layer as a starting point, and it is possible to reliably reflect the light incident on the first light reflecting layer toward the active layer and focused on the active layer. Thus, it is possible to avoid an increase in diffraction loss, and laser oscillation can be reliably performed. Furthermore, since the resonator can be long, it is possible to avoid a problem of thermal saturation. Here, the “thermal saturation” is a phenomenon in which a light output is saturated due to self-heating when the surface emitting laser element is driven. A material used for the light reflecting layer (for example, a material such as SiO₂ or Ta₂O₅) have a lower thermal conductivity value than that of a GaN-based compound semiconductor. Thus, increasing the thickness of the GaN-based compound semiconductor layer leads to suppressing thermal saturation. However, when the thickness of the GaN-based compound semiconductor layer is increased, the length of the resonator length L_{OR} becomes longer, so that a longitudinal mode is likely to change to multiple modes, but in the light emitting element of Example 1, it is possible to obtain a single longitudinal mode even when the resonator length is longer. Furthermore, since the resonator length L_{OR} can be lengthened, tolerance of a manufacturing process of the light emitting element is increased, and as a result, a yield can be improved. The same applies to light emitting elements of various Examples described below.

Instead of the CMP method, the surface of the smoothing layer 44 may be smoothed on the basis of the dipping method. In this case, for example, since the smoothing layer 44 includes Ta₂O₅, it is only required to use HF as the etching solution in the dipping method. Furthermore, the smoothing layer 44 can also include a spin-on-glass based material or a low melting point glass material, and in this case, the smoothing processing on the smoothing layer 44 can be performed on the basis of the CMP method using colloidal silica as a polishing agent, and the smoothing processing on the smoothing layer 44 can be performed on the basis of the dipping method using HF as the etching solution. Furthermore, the material constituting the smoothing layer 44 can also be a semiconductor material, specifically, GaN. In this case, the smoothing processing on the smoothing layer 44 can be performed on the basis of the CMP method using colloidal silica as a polishing agent, and the smoothing processing on the smoothing layer 44 can be performed on the basis of the dipping method using TMAH as the etching solution. Furthermore, the material constituting the smoothing layer 44 can include a resin, specifically an epoxy-based resin, and the smoothing processing on the smoothing layer 44 can be performed on the basis of the CMP method, and the smoothing processing on the smoothing layer 44 can be performed on the basis of the dipping method using halogenated hydrocarbon as the etching solution. However, depending on the resin used, the smoothing processing may not be necessary.

Furthermore, the material constituting the smoothing layer 44 can include, for example, Ta₂O₅, and the smoothing processing on the surface of the smoothing layer 44 is performed on the basis of the dry etching method, specifically, the RIE method (reactive ion etching method).

Furthermore, the laminated structural body 20 can include a GaAs-based compound semiconductor instead of including a GaN-based compound semiconductor, and in this case, it is only required to use a GaAs substrate as the substrate 11. Then, in this case, the smoothing processing on the smoothing layer 44 can be performed on the basis of the CMP method using colloidal silica as the polishing agent, and the smoothing processing on the smoothing layer 44 can be performed on the basis of the dipping method using phosphoric acid/hydrogen peroxide solution as the etching solution. Alternatively, the laminated structural body 20 can include an InP-based compound semiconductor, and in this case, it is only required to use an InP substrate as the substrate 11. Then, in this case, the smoothing processing on the smoothing layer 44 can be performed on the basis of the CMP method using colloidal silica as the polishing agent, and the smoothing processing on the smoothing layer 44 can be performed on the basis of the dipping method using hydrochloric acid as the etching solution.

### Example 2

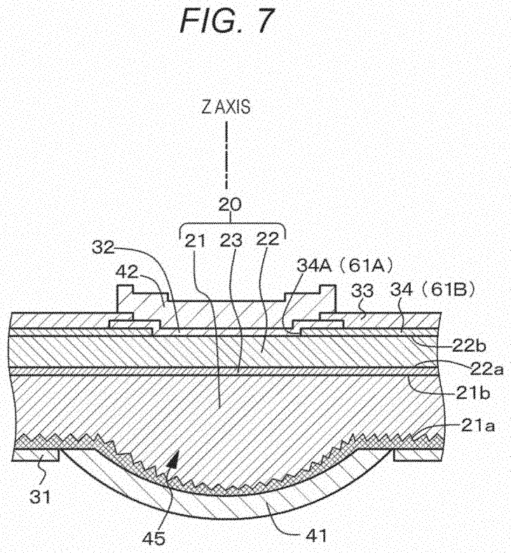

Example 2 is a modification of Example 1. FIG. 7 illustrates a schematic partial end view of a light emitting element of Example 2. In Example 1, the protrusion 43 is formed on the first surface 11a of the substrate 11. On the other hand, in Example 2, a protrusion 45 is formed on the first compound semiconductor layer 21.

In such a light emitting element of Example 2, in a step similar to [Step-130] in the method for manufacturing the light emitting element of Example 1, the substrate 11 is removed from the first surface 11a side to expose the first compound semiconductor layer 21, a resist layer is formed on the first surface 21a of the first compound semiconductor layer 21, and the resist layer is patterned to leave the resist layer on the first compound semiconductor layer 21 on which the protrusion 45 is to be formed. Then, heat processing is performed on the resist layer to form a protrusion in the resist layer. Next, the resist layer and the first compound semiconductor layer 21 are etched back on the basis of the RIE method. In this way, the light emitting element of Example 2 illustrated in FIG. 7 can be finally obtained.

Except for the above points, the configuration and structure of the light emitting element of Example 2 can be similar to the configuration and structure of the light emitting element of Example 1, and thus detailed description thereof will be omitted.

### Example 3

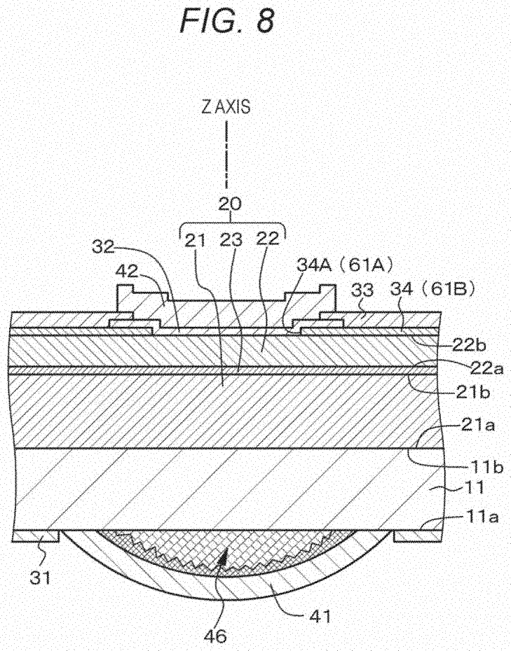

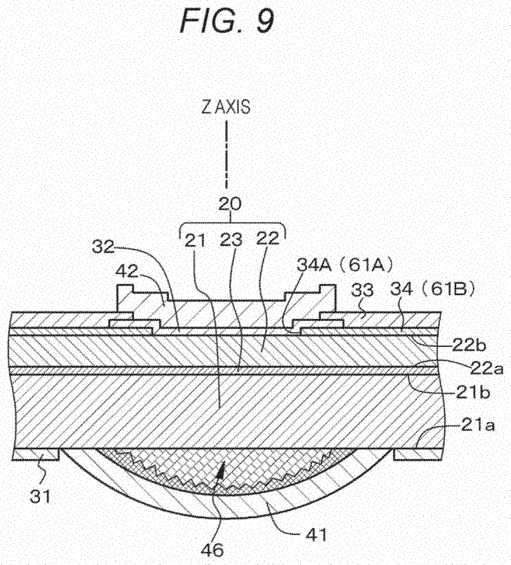

Example 3 is also a modification of Example 1. A schematic partial end view of a light emitting element of Example 3 is illustrated in FIGS. 8 and 9. In Example 3, a protrusion 46 is formed on the first surface 11a of the substrate 11 on the basis of a material different from that of the substrate 11 (see FIG. 8). Alternatively, the protrusion 46 is formed on the exposed surface (first surface 21a) of the first compound semiconductor layer 21 on the basis of a material different from that of the first compound semiconductor layer 21 (see FIG. 9). Here, examples of the material constituting the protrusion 46 include a transparent dielectric material such as TiO₂, Ta₂O₅, or SiO₂, a silicone-based resin, and an epoxy-based resin.

In the light emitting element of Example 3, in a step similar to [Step-130] of Example 1, the substrate 11 is thinned, mirror-finishing is performed, and then the protrusion 46 is formed on the exposed surface (first surface 11a) of the substrate 11. Alternatively, the substrate 11 is removed, mirror-finishing is performed on the first surface 21a of the exposed first compound semiconductor layer 21, and then the protrusion 46 is formed on the exposed surface (first surface 21a) of the first compound semiconductor layer 21. Specifically, for example, on the exposed surface (first surface 11a) of the substrate 11, for example, a TiO₂ layer or a Ta₂O₅ layer is formed, and then a patterned resist layer is formed on the TiO₂ layer or the Ta₂O₅ layer on which the protrusion 46 is to be formed, and the resist layer is heated to reflow the resist layer to obtain a resist pattern. The same shape (or similar shape) as the shape of the protrusion 46 is given to the resist pattern. Then, by etching back the resist pattern and the TiO₂ layer or the Ta₂O₅ layer, the protrusion 46 can be formed on the exposed surface (first surface 11a) of the substrate 11. In this way, the light emitting element of Example 3 illustrated in FIG. 8 can be finally obtained.

Except for the above points, the configuration and structure of the light emitting element of Example 3 can be similar to the configuration and structure of the light emitting element of Example 1, and thus detailed description thereof will be omitted.

### Example 4

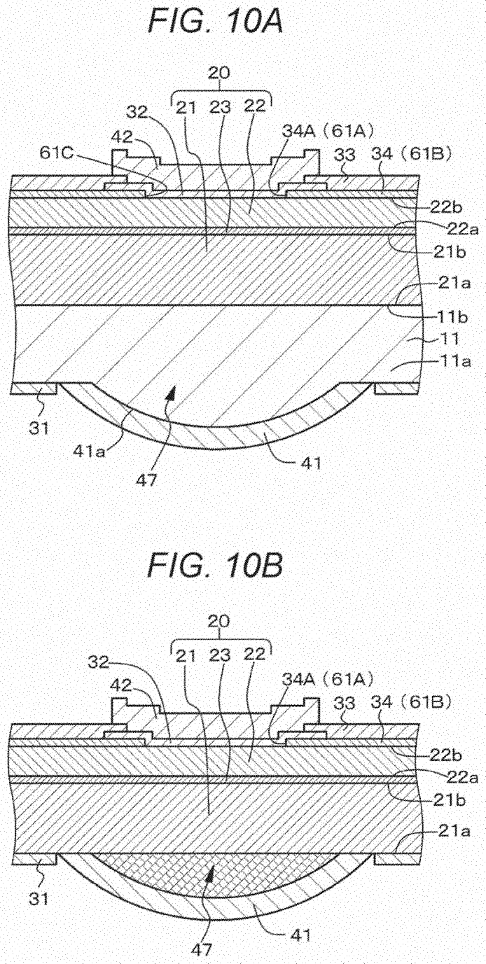

Example 4 relates to a method for manufacturing a light emitting element according to a second aspect of the present disclosure. A schematic partial end view of a light emitting element of Example 4 is illustrated in FIGS. 10A and 10B. In the light emitting element of Example 4,

a protrusion 47 is formed on the first surface side of the first compound semiconductor layer 21,

the protrusion 47 constitutes a concave mirror portion,

the first light reflecting layer 41 is formed on at least the protrusion 47, and

the second light reflecting layer 42 has a flat shape.

Here, a value of the surface roughness Ra₂ of the protrusion 47 at an interface between the protrusion 47 and the first light reflecting layer 41 is equal to or less than 1.0 nm, specifically, is 0.5 nm. Furthermore. A radius of curvature of the protrusion 47 is 1×10⁻⁵ m to 1×10⁻³ m, specifically, is 70 μm. A structure of the protrusion 47 can be the similar to that of the protrusion 43, 45, or 46 of Example 1, Example 2, or Example 3.

Except for the above points, the configuration and structure of the light emitting element of Example 4 can be similar to the configuration and structure of the light emitting element of Example 1, Example 2, or Example 3, and thus detailed description thereof will be omitted.

In a method for manufacturing the light emitting element of Example 4, first, similarly to [Step-100] of Example 1, the laminated structural body 20 is formed in which the first compound semiconductor layer 21, the active layer (light emitting layer) 23, and the second compound semiconductor layer 22 are laminated, the first compound semiconductor layer 21 including the first surface 21a and the second surface 21b facing the first surface 21a, the active layer 23 facing the second surface 21b of the first compound semiconductor layer 21, the second compound semiconductor layer 22 including the first surface 22a facing the active layer 23 and the second surface 22b facing the first surface 22a, and then similarly to [Step-110] to [Step-120], the second electrode 32 and the second light reflecting layer 42 are formed on the second surface 22b of the second compound semiconductor layer 22.

Thereafter, in a step similar to [Step-130] of Example 1, the protrusion 47 is formed on the first surface side of the first compound semiconductor layer 21.

Then, the surface of the protrusion 47 is smoothed. Specifically, since the protrusion 47 includes, for example, a GaN substrate or a first compound semiconductor layer, the smoothing processing on the protrusion 47 can be performed on the basis of the CMP method using colloidal silica as a polishing agent, and the smoothing processing on the protrusion 47 can be performed on the basis of the dipping method using TMAH as the etching solution.

Alternatively, the smoothing processing on the surface of the protrusion 47 can be performed on the basis of the dry etching method, specifically, the RIE method (reactive ion etching method). Here, formation of the protrusion 47 is also performed on the basis of the RIE method, and although depending on an RIE device, it is only required to make an RIE condition in the smoothing processing on the surface of the protrusion 47 more isotropic than an ME condition at this time, that is, to reduce a bias voltage and increase a pressure at etching.

Thereafter, similarly to [Step-160] of Example 1, the first light reflecting layer 41 is formed on at least a part of the protrusion 47, and the first electrode 31 is formed electrically connected to the first compound semiconductor layer 21. In this way, the light emitting element of Example 4 having the structure illustrated in FIG. 10A or FIG. 10B can be obtained.

Hereinafter, before describing Examples 5 to 12, description will be given of various modifications of the light emitting element of the present disclosure, the light emitting element obtained by the method for manufacturing the light emitting element according to the first aspect of the present disclosure, and the light emitting element obtained by the method for manufacturing the light emitting element according to the second aspect of the present disclosure (hereinafter, these light emitting elements are collectively referred to as the “light emitting element and the like of the present disclosure” for convenience).

As described above, the current constriction region (the current injection region 61A and the current non-injection region 61B) is defined by the insulating layer 34 having the opening 34A. That is, the current injection region 61A is defined by the opening 34A. The second compound semiconductor layer 22 is provided with the current injection region 61A and the current non-injection region 61B surrounding the current injection region 61A, and a shortest distance D_{CI} from the area center of gravity of the current injection region 61A to a boundary 61C between the current injection region 61A and the current non-injection region 61B satisfies the following expression. Here, a light emitting element having such a configuration is referred to as a “light emitting element having a first configuration” for convenience. Note that, for derivation of the following expression, see, for example, H. Kogelnik and T. Li, “Laser Beams and Resonators”, Applied Optics/Vol. 5, No. 10/October 1966. Furthermore, ω₀ is also referred to as a beam waist radius.

D_{CI}≥ω₀/2 (A)

where

ω₀²≡(λ₀/π){L_{OR}(R_{DBR}−L_{OR})}^{1/2} (B)

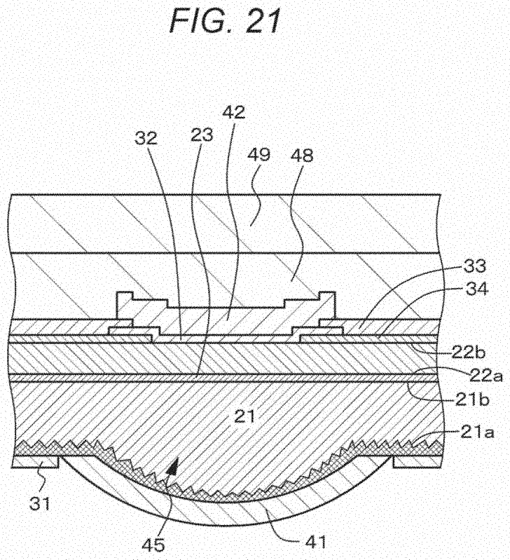

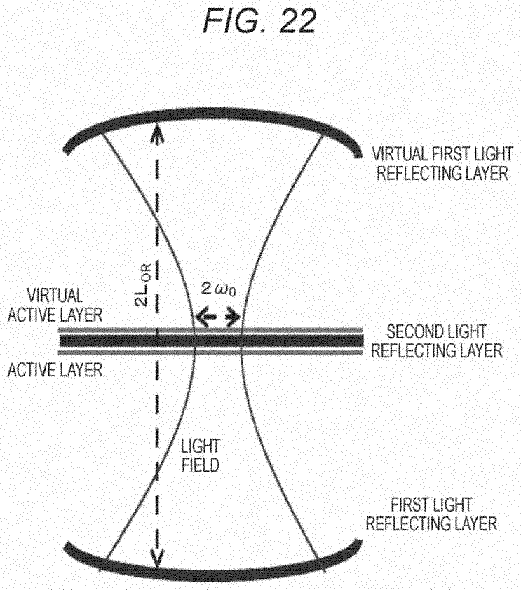

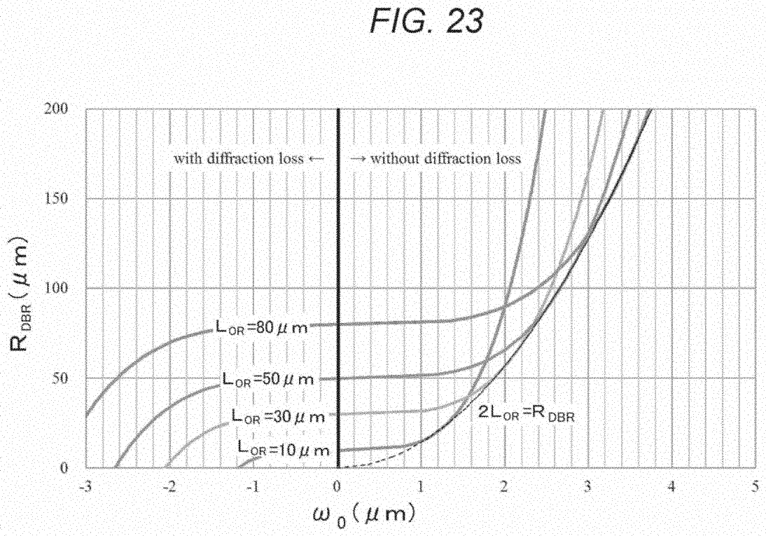

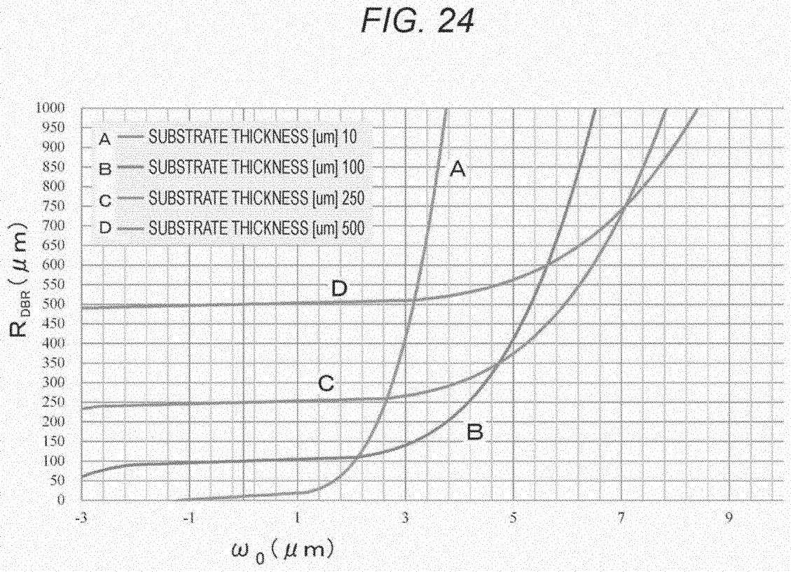

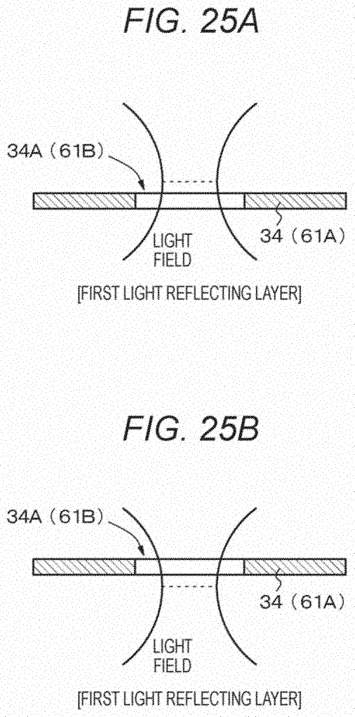

Here, the light emitting element having the first configuration includes the first light reflecting layer that functions as a concave mirror, and considering the symmetry with respect to a flat mirror of the second light reflecting layer, the resonator can be extended to a Fabry-Perot resonator sandwiched between two concave mirrors having the same radius of curvature (see schematic diagram in FIG. 22). At this time, the resonator length of the virtual Fabry-Perot resonator is twice the resonator length L_{OR}. FIGS. 23 and 24 illustrate graphs indicating a relationship between the value of ω₀, the value of the resonator length L_{OR}, and the value of the radius of curvature R_{DBR} of the inner surface of the first light reflecting layer. Note that, the fact that the value of ω₀ is “positive”, means that the laser beam is schematically in a state of FIG. 25A, and the fact that the value of ω₀ is “negative”, means that the laser beam is schematically in a state of FIG. 25B. The state of the laser beam may be the state illustrated in FIG. 25A or the state illustrated in FIG. 25B. However, in the virtual Fabry-Perot resonator having two concave mirrors, when the radius of curvature R_{DBR} is smaller than the resonator length L_{OR}, the state illustrated in FIG. 25B occurs, confinement becomes excessive, and diffraction loss occurs. Thus, it is preferable that the radius of curvature R_{DBR} is larger than the resonator length L_{OR}, which is the state illustrated in FIG. 25A. Note that, when the active layer is arranged close to a flat light reflecting layer, specifically, the second light reflecting layer, of the two light reflecting layers, the light field is more focused in the active layer. That is, light field confinement in the active layer is strengthened, and laser oscillation is facilitated. As the position of the active layer, that is, the distance from a surface of the second light reflecting layer facing the second compound semiconductor layer to the active layer, although not limited thereto, λ₀/2 to 10λ₀ can be exemplified.

By the way, in a case where a region where light reflected by the first light reflecting layer is focused is not included in the current injection region corresponding to a region where the active layer has a gain due to current injection, stimulated emission of light from carriers is hindered, and as a result, the laser oscillation may be hindered. By satisfying the above expressions (A) and (B), it is possible to guarantee that the region where the light reflected by the first light reflecting layer is focused is included in the current injection region, and the laser oscillation can be reliably achieved.

Then, a configuration can be made in which

the light emitting element having the first configuration further includes:

a mode loss action site provided on the second surface of the second compound semiconductor layer and constituting a mode loss action region that acts on an increase or decrease in oscillation mode loss, and

a second electrode formed over the mode loss action site from the second surface of the second compound semiconductor layer, in which

the current injection region, the current non-injection/inner region surrounding the current injection region, and the current non-injection/outer region surrounding the current non-injection/inner region are formed in the laminated structural body, and

an orthographic projection image of the mode loss action region and an orthographic projection image of the current non-injection/outer region overlap each other.

Then, in the light emitting element having the first configuration including such a preferable configuration, the radius r′_{DBR} of the effective region of the first light reflecting layer can be configured to satisfy ω₀≤r′_{DBR}≤20·ω₀, preferably ω₀≤r′_{DBR}≤10·ω₀. Alternatively, as the value of r′_{DBR}, r′_{DBR}≤1×10⁻⁴ m, preferably r′_{DBR}≤5×10⁻⁵ m can be exemplified. Moreover, in the light emitting element having the first configuration including such a preferable configuration, a configuration can be made in which D_{CI}≥ω₀ is satisfied. Moreover, in the light emitting element having the first configuration including such a preferable configuration, a configuration can be made in which R_{DBR}≤1×10⁻³ m, preferably 1×10⁻⁵ m≤R_{DBR}≤1×10⁻³ m, more preferably 1×10⁻⁵ m≤R_{DBR}≤5×10⁻⁴ m.

Furthermore, a configuration can be made in which

the light emitting element and the like of the present disclosure further include

a mode loss action site provided on the second surface of the second compound semiconductor layer and constituting a mode loss action region that acts on an increase or decrease in oscillation mode loss, and

the second electrode formed over the mode loss action site from the second surface of the second compound semiconductor layer, in which

the current injection region, the current non-injection/inner region surrounding the current injection region, and the current non-injection/outer region surrounding the current non-injection/inner region are formed in the laminated structural body, and

an orthographic projection image of the mode loss action region and an orthographic projection image of the current non-injection/outer region overlap each other. Here, a light emitting element having such a configuration is referred to as a “light emitting element having a second configuration” for convenience.

In the light emitting element having the second configuration, the current non-injection region (general term for current non-injection/inner region and current non-injection/outer region) is formed in the laminated structural body, and specifically, the current non-injection region may be formed in a region on the second electrode side of the second compound semiconductor layer in the thickness direction, may be formed in the entire second compound semiconductor layer, may be formed in the second compound semiconductor layer and the active layer, or may be formed over a part of the first compound semiconductor layer from the second compound semiconductor layer. The orthographic projection image of the mode loss action region and the orthographic projection image of the current non-injection/outer region overlap each other, but in a region sufficiently distant from the current injection region, the orthographic projection image of the mode loss action region and the orthographic projection image of the current non-injection/outer region do not have to overlap each other.

In the light emitting element having the second configuration, the current non-injection/outer region can be configured to be located below the mode loss action region.

In the light emitting element having the second configuration including the preferable configuration described above, when an area of the orthographic projection image of the current injection region is S₁ and an area of the orthographic projection image of the current non-injection/inner region is S₂, a configuration can be made in which

0.01≤S₁/(S₁+S₂)≤0.7

is satisfied.

In the light emitting element having the second configuration including the preferable configuration described above, the current non-injection/inner region and the current non-injection/outer region can be configured to be formed by ion implantation into the laminated structural body. A light emitting element having such a configuration is referred to as a “light emitting element having a second configuration A” for convenience. Then, in this case, a configuration can be made in which an ion species is at least one ion (that is, one ion, or greater than or equal to two ions) selected from a group consisting of boron, proton, phosphorus, arsenic, carbon, nitrogen, fluorine, oxygen, germanium, and silicon.

Alternatively, in the light emitting element having the second configuration including the preferable configuration described above, the current non-injection/inner region and the current non-injection/outer region can be configured to be formed by plasma irradiation onto the second surface of the second compound semiconductor layer, ashing processing onto the second surface of the second compound semiconductor layer, or reactive ion etching (ME) processing onto the second surface of the second compound semiconductor layer. A light emitting element having such a configuration is referred to as a “light emitting element having a second configuration B” for convenience. In these pieces of processing, the current non-injection/inner region and the current non-injection/outer region are exposed to plasma particles, so that conductivity of the second compound semiconductor layer degrades, and the current non-injection/inner region and the current non-injection/outer region are in a high resistance state. That is, the current non-injection/inner region and the current non-injection/outer region can be configured to be formed by exposure to the plasma particles on the second surface of the second compound semiconductor layer. Specific examples of the plasma particles include argon, oxygen, nitrogen, and the like.

Alternatively, in the light emitting element having the second configuration including the preferable configuration described above, the second light reflecting layer can include a region that reflects or scatters light from the first light reflecting layer toward the outside of a resonator structure including the first light reflecting layer and the second light reflecting layer. A light emitting element having such a configuration is referred to as a “light emitting element having a second configuration C” for convenience. Specifically, a region of the second light reflecting layer located above a side wall of the mode loss action site (a side wall of the opening provided in the mode loss action site) has a forward tapered inclination. Furthermore, a configuration can also be adopted in which light is scattered toward the outside of the resonator structure including the first light reflecting layer and the second light reflecting layer by scattering light at a boundary (side wall edge portion) between the top surface of the mode loss action site and the side wall of the opening provided in the mode loss action site.

In the light emitting element having the second configuration A, the light emitting element having the second configuration B, or the light emitting element having the second configuration C described above, a configuration can be made in which when an optical distance from the active layer in the current injection region to the second surface of the second compound semiconductor layer is L₂, and an optical distance from the active layer in the mode loss action region to the top surface of the mode loss action site is L₀,

L₀>L₂

is satisfied. Moreover, in the light emitting element having the second configuration A, the light emitting element having the second configuration B, or the light emitting element having the second configuration C described above and including such a configuration, a configuration can be made in which light having a higher-order mode generated is dissipated toward the outside of the resonator structure including the first light reflecting layer and the second light reflecting layer by the mode loss action region, and thus the oscillation mode loss is increased. That is, due to the presence of the mode loss action region that acts on an increase or decrease of the oscillation mode loss, generated light field intensities of a basic mode and the higher-order mode decrease as the distance from the Z axis increases in the orthographic projection image of the mode loss action region, but the mode loss in the higher-order mode is larger than the decrease in the light field intensity of the basic mode, and the basic mode can be further stabilized, and the mode loss can be suppressed as compared with a case where the current injection inner region does not exist, so that a threshold current can be reduced.

Furthermore, in the light emitting element having the second configuration A, the light emitting element having the second configuration B, or the light emitting element having the second configuration C described above, the mode loss action site can include a dielectric material, a metal material, or an alloy material. As the dielectric material, SiO_{X}, SiN_{X}, AlN_{X}, AlO_{X}, TaO_{X}, ZrO_{X} can be exemplified, and as the metal material or alloy material, titanium, gold, platinum, or an alloy thereof can be exemplified; however, the materials are not limited thereto. It is possible to cause the mode loss action site including these materials to absorb light, and increase the mode loss. Alternatively, even if the light is not directly absorbed, mode loss can be controlled by disturbing the phase. In this case, a configuration can be made in which the mode loss action site includes a dielectric material, and an optical thickness t₀ of the mode loss action site has a value deviating from an integral multiple of ¼ of the oscillation wavelength λ₀. That is, it is possible to destroy a standing wave by disturbing the phase of the light that circulates in the resonator and forms the standing wave, at the mode loss action site, and to give a corresponding mode loss. Alternatively, a configuration can be made in which the mode loss action site includes a dielectric material, and the optical thickness t₀ of the mode loss action site (refractive index is nm-loss) is an integral multiple of ¼ of the oscillation wavelength λ₀. That is, a configuration can be made in which the optical thickness t₀ of the mode loss action site is a thickness at which the phase of the light generated in the light emitting element is not disturbed and the standing wave is not destroyed. However, it does not have to be exactly an integral multiple of ¼, and it is only required to satisfy

(λ₀/4nₘ₋ₗₒₛₛ)×m−(λ₀/8nₘ₋ₗₒₛₛ)≤t₀≤(λ₀/4nₘ₋ₗₒₛₛ)×2m+(λ₀/8nₘ₋ₗₒₛₛ).

Alternatively, by forming the mode loss action site to include a dielectric material, a metal material, or an alloy material, it is possible to cause the mode loss action site to disturb the phase or absorb the light passing through the mode loss action site. Then, by adopting these configurations, the oscillation mode loss can be controlled with a higher degree of freedom, and a degree of freedom in designing the light emitting element can be further increased.

Alternatively, in the light emitting element having the second configuration including the preferable configuration described above, a configuration can be made in which

a protruding portion is formed on the second surface side of the second compound semiconductor layer, and

the mode loss action site is formed on a region of the second surface of the second compound semiconductor layer surrounding the protruding portion. A light emitting element having such a configuration is referred to as a “light emitting element having a second configuration D” for convenience. The protruding portion occupies the current injection region and the current non-injection/inner region. Then, in this case, a configuration can be made in which when the optical distance from the active layer in the current injection region to the second surface of the second compound semiconductor layer is L₂, and the optical distance from the active layer in the mode loss action region to the top surface of the mode loss action site is L₀,

L₀<L₂

is satisfied, and moreover, in these cases, a configuration can be made in which light having the higher-order mode generated is confined in the current injection region and the current non-injection/inner region by the mode loss action region, and thus the oscillation mode loss is reduced. That is, due to the presence of the mode loss action region that acts on an increase or decrease of the oscillation mode loss, generated light field intensities of the basic mode and the higher-order mode increase in the orthographic projection images of the current injection region and the current non-injection/inner region. Moreover, in these cases, the mode loss action site can include a dielectric material, a metal material, or an alloy material. Here, as the dielectric material, the metal material, or the alloy material, the above-mentioned various materials can be mentioned.

Moreover, in the light emitting element and the like of the present disclosure including the preferable modes and configurations (including the light emitting element having the first configuration to the light emitting element having the second configuration) described above, a configuration can be made in which at least two light absorbing material layers are formed in parallel with a virtual plane occupied by the active layer, in the laminated structural body including the second electrode. Here, a light emitting element having such a configuration is referred to as a “light emitting element having a third configuration” for convenience. In the light emitting element having the third configuration, it is preferable that at least four light absorbing material layers are formed.

In the light emitting element having the third configuration including the preferable configuration described above, when the oscillation wavelength (wavelength of light mainly emitted from the light emitting element, and is a desired oscillation wavelength) is λ₀, an overall equivalent refractive index of the two light absorbing material layers and a portion of the laminated structural body located between the light absorbing material layer and the light absorbing material layer is n_{eq}, and a distance between the light absorbing material layer and the light absorbing material layer is L_{Abs}, it is preferable to satisfy

0.9×{(m·λ₀)/(2·n_{eq})}≤L_{Abs}≤1.1×{(m·λ₀)/(2·n_{eq})}.

Here, m is 1 or any integer greater than or equal to 2 including 1. When a thickness of each of layers constituting the two light absorbing material layers and the portion of the laminated structural body located between the light absorbing material layer and the light absorbing material layer is tᵢ, and each refractive index is nᵢ, the equivalent refractive index n_{eq} is represented by

n_{eq}Σ(tᵢ×nᵢ)/Σ(tᵢ).

However, i=1, 2, 3 . . . , I, and “I” is a total number of layers constituting the two light absorbing material layers and the portion of the laminated structural body located between the light absorbing material layer and the light absorbing material layer, and “Σ” means to take a sum total from i=1 to i=I. The equivalent refractive index n_{eq} is only required to be calculated by observing constituent materials from electron microscope observation of a cross section of the light emitting element, or the like, and on the basis of the known refractive index and the thickness obtained by the observation, for each constituent material. In a case where m is 1, a distance between adjacent light absorbing material layers satisfies

0.9×{λ₀/(2·n_{eq})}≤L_{Abs}≤1.1×{λ₀/(2·n_{eq})}

in all multiple light absorbing material layers. Furthermore, when m is any integer of greater than or equal to 2 including 1, for example, if m=1, 2, in some light absorbing material layers, the distance between adjacent light absorbing material layers satisfies

0.9×{λ₀/(2·n_{eq})}≤L_{Abs}≤1.1×{λ₀/(2·n_{eq})}, and

in remaining light absorbing material layers, the distance between adjacent light absorbing material layers satisfies

0.9×{(2·λ₀)/(2·n_{eq})}≤L_{Abs}≤1.1×{(2·λ₀)/(2·n_{eq})}.

Broadly, in some light absorbing material layers, the distance between adjacent light absorbing material layers satisfies

0.9×{λ₀/(2·n_{eq})}≤L_{Abs}≤1.1×{λ₀/(2·n_{eq})}, and

in remaining various light absorbing material layers, the distance between adjacent light absorbing material layers satisfies

0.9×{(m′·λ₀)/(2·n_{eq})}≤L_{Abs}≤1.1×{(m′·λ₀)/(2·n_{eq})}.

Here, m′ is any integer greater than or equal to 2. Furthermore, the distance between adjacent light absorbing material layers is a distance between the centers of gravity of adjacent light absorbing material layers. That is, actually, it is a distance between the centers of respective light absorbing material layers when cut in a virtual plane along the thickness direction of the active layer.

Moreover, in the light emitting element having the third configuration including the various preferable configurations described above, the thickness of the light absorbing material layer is preferably less than or equal to λ₀/(4·n_{eq}). As a lower limit value of the thickness of the light absorbing material layer, 1 nm can be exemplified.

Moreover, in the light emitting element having the third configuration including the various preferable configurations described above, a configuration can be made in which the light absorbing material layer is located at a minimum amplitude portion generated in the standing wave of light formed inside the laminated structural body.

Moreover, in the light emitting element having the third configuration including the various preferable configurations described above, a configuration can be made in which the active layer is located at a maximum amplitude portion generated in the standing wave of light formed inside the laminated structural body.

Moreover, in the light emitting element having the third configuration including the various preferable configurations described above, a configuration can be made in which the light absorbing material layer has a light absorption coefficient of twice or more a light absorption coefficient of the compound semiconductor constituting the laminated structural body. Here, the light absorption coefficient of the light absorbing material layer and the light absorption coefficient of the compound semiconductor constituting the laminated structural body can be obtained by observing constituent materials from electron microscope observation of a cross section of the light emitting element, or the like, and inferring the coefficient from known evaluation results observed for the respective constituent materials.

Moreover, in the light emitting element having the third configuration including the various preferable configurations described above, a configuration can be made in which the light absorbing material layer includes at least one material selected from a group consisting of a compound semiconductor material having a narrower bandgap than the compound semiconductor constituting the laminated structural body, a compound semiconductor material doped with impurities, a transparent conductive material, and a light reflecting layer constituent material having light absorption characteristics. Here, as the compound semiconductor material having a narrower bandgap than the compound semiconductor constituting the laminated structural body, for example, in a case where the compound semiconductor constituting the laminated structural body is GaN, InGaN can be mentioned; as the compound semiconductor material doped with impurities, Si-doped n-GaN and B-doped n-GaN can be mentioned; as the transparent conductive material, a transparent conductive material constituting an electrode can be mentioned; and as the light reflecting layer constituent material having light absorption characteristics, a material constituting the light reflecting layer (for example, SiO_{X}, SiN_{X}, TaO_{X}, or the like) can be mentioned. All of the light absorbing material layers may include one of these materials. Alternatively, each of the light absorbing material layers may include various materials selected from these materials, but it is preferable that one light absorbing material layer includes one material, from a viewpoint of simplification of formation of the light absorbing material layer. The light absorbing material layer may be formed in the first compound semiconductor layer, may be formed in the second compound semiconductor layer, or may be formed in the second light reflecting layer, or any combination of these can be used. Alternatively, the light absorbing material layer can also be used as an electrode including a transparent conductive material.

Hereinafter, Examples 5 to 12 will be described.

### Example 5

Example 5 is a modification of Examples 1 to 4, and relates to the light emitting element having the first configuration. As described above, the current constriction region (the current injection region 61A and the current non-injection region 61B) is defined by the insulating layer 34 having the opening 34A. That is, the current injection region 61A is defined by the opening 34A. That is, in the light emitting element of Example 5, the second compound semiconductor layer 22 is provided with the current injection region 61A and the current non-injection region 61B surrounding the current injection region 61A, and the shortest distance D_{CI} from the area center of gravity of the current injection region 61A to the boundary 61C between the current injection region 61A and the current non-injection region 61B satisfies the expressions (A) and (B) described above.

In the light emitting element of Example 5, the radius r′_{DBR} of the effective region 41b of the first light reflecting layer 41 satisfies

ω₀<r′_{DBR}≤20·ω₀.

Furthermore, D_{CI}≥ω₀ is satisfied. Moreover, R_{DBR}≤1×10⁻³ m is satisfied. Specifically,

D_{CI}=4 μm

ω₀=1.5 μm

L_{OR}=30 μm

R_{DBR}=60 μm

λ₀=525 nm

can be exemplified. Furthermore, 8 μm can be exemplified as the diameter of the opening 34A. As the GaN substrate, a substrate is used whose main surface is a surface in which c-plane is tilted by about 75 degrees in the m-axis direction. That is, the GaN substrate includes the {20-21} plane that is a semi-polar plane, as a main surface. Note that, such a GaN substrate can also be used in other Examples.

The deviation between the central axis (Z axis) of the protrusion and the current injection region 61A in the XY plane direction causes degradation of the characteristics of the light emitting element. Lithography technology is often used for both patterning for forming the protrusion and patterning for forming the opening 34A, but in this case, a positional relationship between the two often deviates within the XY plane depending on performance of an exposure machine. In particular, the opening 34A (current injection region 61A) is positioned by alignment from the second compound semiconductor layer 22 side. On the other hand, the protrusion is positioned by alignment from the compound semiconductor substrate 11 side. Thus, in the light emitting element of Example 5, the opening 34A (current injection region 61) is formed larger than a region where light is focused by the protrusion, whereby a structure is implemented in which oscillation characteristics are not affected even if there is a deviation between the central axis (Z axis) and the current injection region 61A in the XY plane direction.

That is, in a case where a region where light reflected by the first light reflecting layer is focused is not included in the current injection region corresponding to a region where the active layer has a gain due to current injection, stimulated emission of light from carriers is hindered, and as a result, laser oscillation may be hindered. However, by satisfying the above expressions (A) and (B), it can be guaranteed that the region where the light reflected by the first light reflecting layer is focused is included in the current injection region, and the laser oscillation can be reliably achieved.

### Example 6

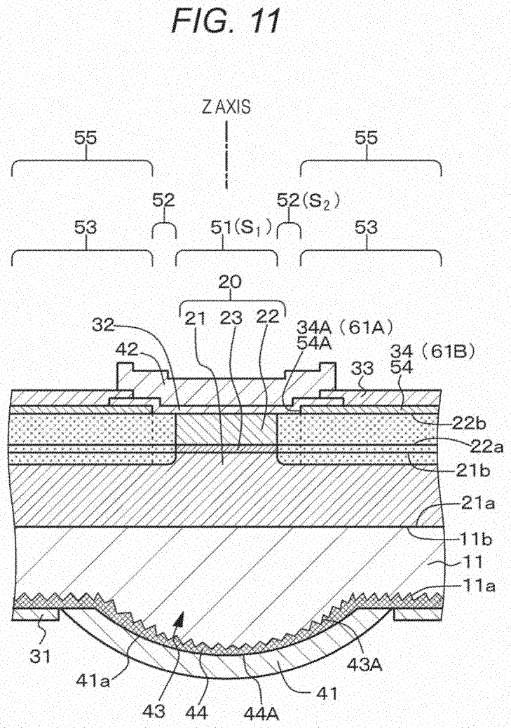

Example 6 is a modification of Examples 1 to 5, and relates to the light emitting element having the second configuration, specifically, the light emitting element having the second configuration A. FIG. 11 illustrates a schematic partial end view of the light emitting element of Example 6.

By the way, to control a flow path (current injection region) of a current flowing between the first electrode and the second electrode, the current non-injection region is formed to surround the current injection region. In a GaAs-based surface emitting laser element (a surface emitting laser element including a GaAs-based compound semiconductor), the current non-injection region surrounding the current injection region can be formed by oxidizing the active layer from the outside along the XY plane. An oxidized active layer region (current non-injection region) has a lower refractive index than a non-oxidized region (current injection region). As a result, the optical path length of the resonator (represented by the product of the refractive index and the physical distance) is shorter in the current non-injection region than in the current injection region. Then, as a result, a kind of “lens effect” is generated, and an action of confining the laser beam in the central portion of the surface emitting laser element is brought about. In general, since light tends to spread due to a diffraction effect, the laser beam reciprocating in the resonator gradually dissipates to the outside of the resonator (diffraction loss), which causes an adverse effect such as an increase in threshold current. However, since the lens effect compensates for the diffraction loss, it is possible to suppress an increase in the threshold current and the like.

However, in a light emitting element including a GaN-based compound semiconductor, it is difficult to oxidize the active layer from the outside (from the lateral direction) along the XY plane due to the characteristics of the material. Thus, as described in Examples 1 to 5, the insulating layer 34 including SiO₂ including the opening 34A is formed on the second compound semiconductor layer 22, the second electrode 32 including a transparent conductive material is formed over the insulating layer 34 from the second compound semiconductor layer 22 exposed at the bottom of the opening 34A, and the second light reflecting layer 42 including laminated structure of an insulating material is formed on the second electrode 32. By forming the insulating layer 34 in this way, the current non-injection region 61B is formed. Then, a portion of the second compound semiconductor layer 22 located in the opening 34A provided in the insulating layer 34 becomes the current injection region 61A.

In a case where the insulating layer 34 is formed on the second compound semiconductor layer 22, the resonator length in the region where the insulating layer 34 is formed (current non-injection region 61B) is longer than the resonator length in the region where the insulating layer 34 is not formed (current injection region 61A) by the optical thickness of the insulating layer 34. Thus, an action occurs in which the laser beam reciprocating in the resonator formed by the two light reflecting layers 41 and 42 of the surface emitting laser element (light emitting element) is diverged and dissipated to the outside of the resonator. For convenience, such an action is referred to as a “reverse lens effect”. Then, as a result, oscillation mode loss occurs in the laser beam, and there is a possibility that the threshold current increases or the slope efficiency degrades. Here, the “oscillation mode loss” is a physical quantity that increases or decreases the light field intensity of the basic mode and the higher-order mode in the oscillating laser beam, and different oscillation mode losses are defined for respective modes. Note that, the “light field intensity” is a light field intensity with a distance L from the Z axis in the XY plane as a function, and in general, in the basic mode, the light field intensity decreases monotonically as the distance L increases, but in the higher-order mode, the light field intensity increases and decreases once or multiple times and then decreases, as the distance L increases (see the conceptual diagram in (A) of FIG. 13). Note that, in FIG. 13, the solid line illustrates the light field intensity distribution in the basic mode, and the broken line illustrates the light field intensity distribution in the higher-order mode. Furthermore, in FIG. 13, the first light reflecting layer 41 is displayed in a flat state for convenience, but it is actually formed on the protrusion.

The light emitting element of Example 6 or each light emitting element of Examples 7 to 9 described later includes:

(A) the laminated structural body 20 including a GaN-based compound semiconductor in which

the first compound semiconductor layer 21 including the first surface 21a and the second surface 21b facing the first surface 21a,

the active layer (light emitting layer) 23 facing the second surface 21b of the first compound semiconductor layer 21, and

the second compound semiconductor layer 22 including the first surface 22a facing the active layer 23 and the second surface 22b facing the first surface 22a are laminated;

(B) a mode loss action site (mode loss action layer) 54 provided on the second surface 22b of the second compound semiconductor layer 22 and constituting a mode loss action region 55 that acts on an increase or decrease in oscillation mode loss;

(C) the second electrode 32 formed over the mode loss action site 54 from the second surface 22b of the second compound semiconductor layer 22;

(D) the second light reflecting layer 42 formed on the second electrode 32;

(E) the first light reflecting layer 41;

(F) the first electrode 31; and

(G) the protrusion 45, 46, 47, or protrusion 43, and the smoothing layer 44.

Then, in the laminated structural body 20, a current injection region 51, a current non-injection/inner region 52 surrounding the current injection region 51, and a current non-injection/outer region 53 surrounding the current non-injection/inner region 52 are formed, and an orthographic projection image of the mode loss action region 55 and an orthographic projection image of the current non-injection/outer region 53 overlap each other. That is, the current non-injection/outer region 53 is located below the mode loss action region 55. Note that, in a region sufficiently distant from the current injection region 51 in which the current is injected, the orthographic projection image of the mode loss action region 55 and the orthographic projection image of the current non-injection/outer region 53 do not have to overlap each other. Here, in the laminated structural body 20, the current non-injection regions 52 and 53 are formed in which no current is injected, and in the illustrated example, it is formed over a part of the first compound semiconductor layer 21 from the second compound semiconductor layer 22, in the thickness direction. However, the current non-injection regions 52 and 53 may be formed in a region on the second electrode side of the second compound semiconductor layer 22, in the thickness direction, may be formed in the entire second compound semiconductor layer 22, or may be formed on the second compound semiconductor layer 22 and the active layer 23.

The mode loss action site (mode loss action layer) 54 includes a dielectric material such as SiO₂, and is formed between the second electrode 32 and the second compound semiconductor layer 22, in the light emitting element of Example 6 or Examples 7 to 9 described later. The optical thickness of the mode loss action site 54 can be set to a value deviating from an integral multiple of ¼ of the oscillation wavelength λ₀. Alternatively, the optical thickness to of the mode loss action site 54 can be set to an integral multiple of ¼ of the oscillation wavelength λ₀. That is, the optical thickness t₀ of the mode loss action site 54 can be set to a thickness that does not disturb the phase of the light generated in the light emitting element and does not destroy the standing wave. However, it does not have to be exactly an integral multiple of ¼, and it is only required to satisfy

(λ₀/4nₘ₋ₗₒₛₛ)×m−(λ₀/8nₘ₋ₗₒₛₛ)≤t₀≤(λ₀/4nₘ₋ₗₒₛₛ)×2m+(λ₀/8nₘ₋ₗₒₛₛ).

Specifically, the optical thickness t₀ of the mode loss action site 54 is preferably about 25 to 250 when a value of ¼ of the wavelength of the light generated by the light emitting element is “100”. Then, by adopting these configurations, it is possible to change a phase difference (control the phase difference) between the laser beam passing through the mode loss action site 54 and the laser beam passing through the current injection region 51, and the oscillation mode loss can be controlled with a higher degree of freedom, and a degree of freedom in designing the light emitting element can be further increased.

In Example 6, a shape of a boundary between the current injection region 51 and the current non-injection/inner region 52 is circular (diameter: 8 μm), and a shape of a boundary between the current non-injection/inner region 52 and the current non-injection/outer region 53 is circular (diameter: 12 μm). That is, when an area of an orthographic projection image of the current injection region 51 is S₁ and an area of an orthographic projection image of the current non-injection/inner region 52 is S₂,

0.01≤S₁/(S₁+S₂)≤0.7

is satisfied. Specifically,

S₁/(S₁+S₂)=8²/12²=0.44.

In the light emitting element of Example 6 or Examples 7 to 8 described later, when the optical distance from the active layer 23 in the current injection region 51 to the second surface of the second compound semiconductor layer 22 is L₂, and the optical distance from the active layer 23 in the mode loss action region 55 to the top surface of the mode loss action site 54 (the surface facing the second electrode 32) is L₀,

L₀>L₂

is satisfied. Specifically,

L₀/L₂=1.5

is set. Then, the generated laser beam having the higher-order mode is dissipated toward the outside of the resonator structure including the first light reflecting layer 41 and the second light reflecting layer 42 by the mode loss action region 55, and thus the oscillation mode loss increases. That is, due to the presence of the mode loss action region 55 that acts on an increase or decrease of the oscillation mode loss, generated light field intensities of the basic mode and the higher-order mode decrease as the distance from the Z axis increases in the orthographic projection image of the mode loss action region 55 (see the conceptual diagram of (B) in FIG. 13), but the decrease in the light field intensity in the higher-order mode is larger than the decrease in the light field intensity of the basic mode, and the basic mode can be further stabilized, the threshold current can be reduced, and the relative light field intensity in the basic mode can be increased. Moreover, a hem portion of the light field intensity in the higher-order mode is located farther from the current injection region than the conventional light emitting element (see (A) of FIG. 13), so that the influence of the reverse lens effect can be reduced. Note that, in the first place, in a case where the mode loss action site 54 including SiO₂ is not provided, oscillation mode mix occurs.

The first compound semiconductor layer 21 includes an n-GaN layer; the active layer 23 includes a five-layered multiple quantum well structure in which an In_{0.04}Ga_{0.96}N layer (barrier layer) and an In_{0.16}Ga_{0.84}N layer (well layer) are laminated; and the second compound semiconductor layer 22 includes a p-GaN layer. Furthermore, the first electrode 31 includes Ti/Pt/Au, and the second electrode 32 includes a transparent conductive material, specifically, ITO. A circular opening 54A is formed at the mode loss action site 54, and the second compound semiconductor layer 22 is exposed at the bottom of the opening 54A. On the edge of the first electrode 31, a pad electrode (not illustrated) including, for example, Ti/Pt/Au or V/Pt/Au for electrically connecting to an external electrode or circuit is formed or connected. On the edge of the second electrode 32, the pad electrode 33 is formed or connected including, for example, Ti/Pd/Au or Ti/Ni/Au for electrically connecting to an external electrode or circuit. The first light reflecting layer 41 and the second light reflecting layer 42 include a laminated structure of a SiN layer and a SiO₂ layer (total number of laminated layers of dielectric films: 20 layers).

In the light emitting element of Example 6, the current non-injection/inner region 52 and the current non-injection/outer region 53 are formed by ion implantation into the laminated structural body 20. For example, boron was selected as the ion species, but the ion species is not limited to boron ions.

An outline of a method for manufacturing the light emitting element of Example 6 will be described below.

[Step-600] In manufacturing the light emitting element of Example 6, first, a step similar to [Step-100] of Example 1 is executed.

### [Step-610]

Next, on the basis of an ion implantation method using boron ions, the current non-injection/inner region 52 and the current non-injection/outer region 53 are formed in the laminated structural body 20.

### [Step-620]

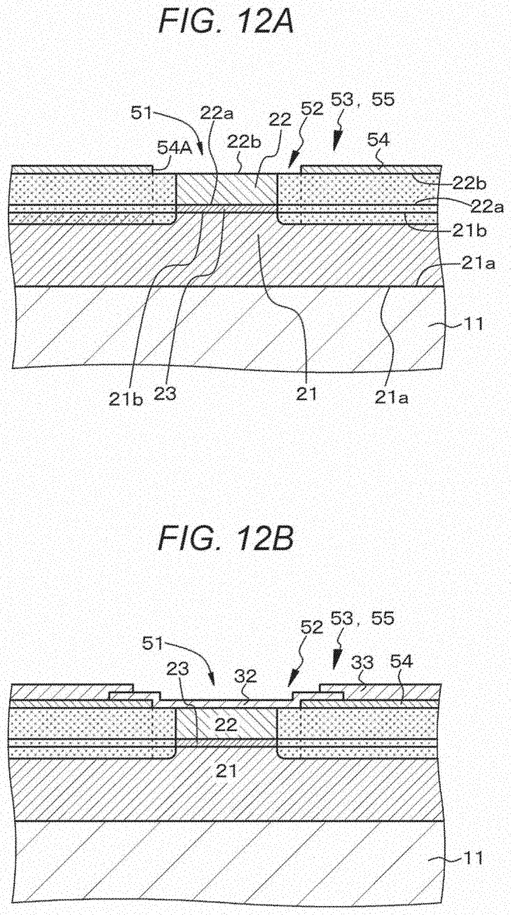

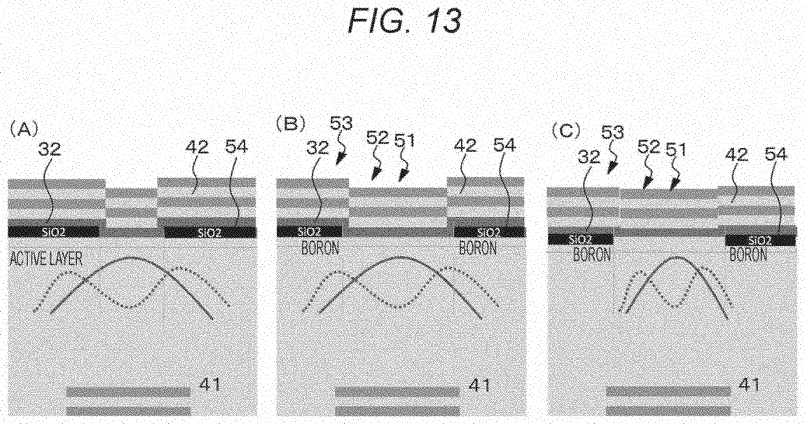

Thereafter, in the step similar to [Step-110] of Example 1, the mode loss action site (mode loss action layer) 54 including the opening 54A and including SiO₂ is formed on the second surface 22b of the second compound semiconductor layer 22 on the basis of a well-known method (see FIGS. 12A and 12B).

### [Step-630]

Thereafter, the light emitting element of Example 6 can be obtained by executing steps similar to [Step-120] to [Step-160] of Example 1.

In the light emitting element of Example 6, the current injection region, the current non-injection/inner region surrounding the current injection region, and the current non-injection/outer region surrounding the current non-injection/inner region are formed in the laminated structural body, and the orthographic projection image of the mode loss action region and the orthographic projection image of the current non-injection/outer region overlap each other. That is, the current injection region and the mode loss action region are separated (disconnected) by the current non-injection/inner region. Thus, as illustrated in the conceptual diagram in (B) of FIG. 13, it is possible to make increase/decrease of the oscillation mode loss (specifically, increase in Example 6) a desired state. Alternatively, it is possible to make increase/decrease of the oscillation mode loss a desired state by appropriately determining a positional relationship between the current injection region and the mode loss action region, the thickness of the mode loss action site constituting the mode loss action region, and the like. Then, as a result, it is possible to solve problems in the conventional light emitting element, for example, an increase in the threshold current and a degradation in the slope efficiency. For example, the threshold current can be reduced by reducing the oscillation mode loss in the basic mode. Moreover, since a region where the oscillation mode loss is given and a region where the current is injected and that contributes to light emission can be controlled independently, that is, control of the oscillation mode loss and control of a light emitting state of the light emitting element can be performed independently, a degree of freedom in control and a degree of freedom in designing the light emitting element can be increased. Specifically, by setting the current injection region, the current non-injection region, and the mode loss action region in the predetermined arrangement relationship described above, it is possible to control a magnitude relationship of the oscillation mode loss given by the mode loss action region to the basic mode and the higher-order mode, and the basic mode can be further stabilized by making the oscillation mode loss given to the higher-order mode relatively large with respect to the oscillation mode loss given to the basic mode. Moreover, since the light emitting element of Example 6 also includes a protrusion, occurrence of the diffraction loss can be suppressed more reliably.

### Example 7

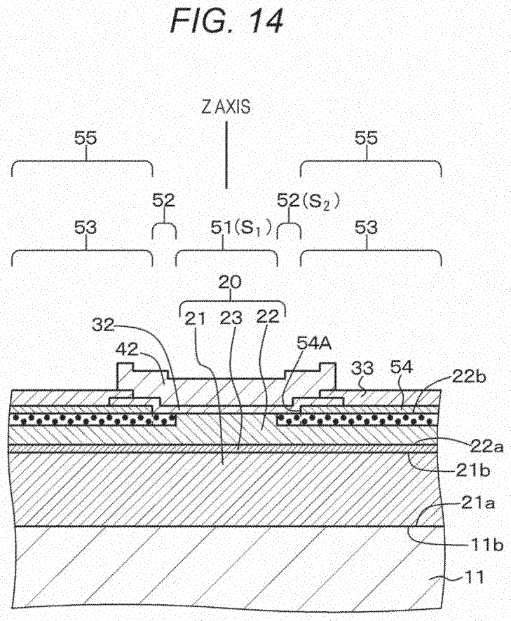

Example 7 is a modification of Example 6 and relates to a light emitting element having the second configuration B. As illustrated in a schematic partial end view in FIG. 14, in the light emitting element of Example 7, the current non-injection/inner region 52 and the current non-injection/outer region 53 are formed by plasma irradiation onto the second surface of the second compound semiconductor layer 22, ashing processing onto the second surface of the second compound semiconductor layer 22, or reactive ion etching (ME) processing onto the second surface of the second compound semiconductor layer 22. Then, since the current non-injection/inner region 52 and the current non-injection/outer region 53 are exposed to plasma particles (specifically, argon, oxygen, nitrogen, and the like), degradation occurs in the conductivity of the second compound semiconductor layer 22, and the current non-injection/inner region 52 and the current non-injection/outer region 53 are in a high resistance state. That is, the current non-injection/inner region 52 and the current non-injection/outer region 53 are formed by exposure of the second surface 22b of the second compound semiconductor layer 22 to the plasma particles. Note that, in FIGS. 14, 15, 16, and 17, the first electrode 31, the protrusions 43, 45, 46, and 47, and the smoothing layer 44 are not illustrated.

Also in Example 7, the shape of the boundary between the current injection region 51 and the current non-injection/inner region 52 is circular (diameter: 10 μm), and the shape of the boundary between the current non-injection/inner region 52 and the current non-injection/outer region 53 is circular (diameter: 15 μm). That is, when an area of an orthographic projection image of the current injection region 51 is S₁ and an area of an orthographic projection image of the current non-injection/inner region 52 is S₂,

0.01≤S₁/(S₁+S₂)≤0.7

is satisfied. Specifically,

S₁/(S₁+S₂)=10²/15²=0.44.

In Example 7, it is only required to form the current non-injection/inner region 52 and the current non-injection/outer region 53 in the laminated structural body 20 on the basis of the plasma irradiation onto the second surface of the second compound semiconductor layer 22, the ashing processing onto the second surface of the second compound semiconductor layer 22, or the reactive ion etching processing onto the second surface of the second compound semiconductor layer 22, instead of [Step-610] of Example 6.

Except for the above points, the configuration and structure of the light emitting element of Example 7 can be similar to the configuration and structure of the light emitting element of Example 6, and thus detailed description thereof will be omitted.

Even in the light emitting element of Example 7 or Example 8 described later, by setting the current injection region, the current non-injection region, and the mode loss action region in the predetermined arrangement relationship described above, it is possible to control a magnitude relationship of the oscillation mode loss given by the mode loss action region to the basic mode and the higher-order mode, and the basic mode can be further stabilized by making the oscillation mode loss given to the higher-order mode relatively large with respect to the oscillation mode loss given to the basic mode.

### Example 8

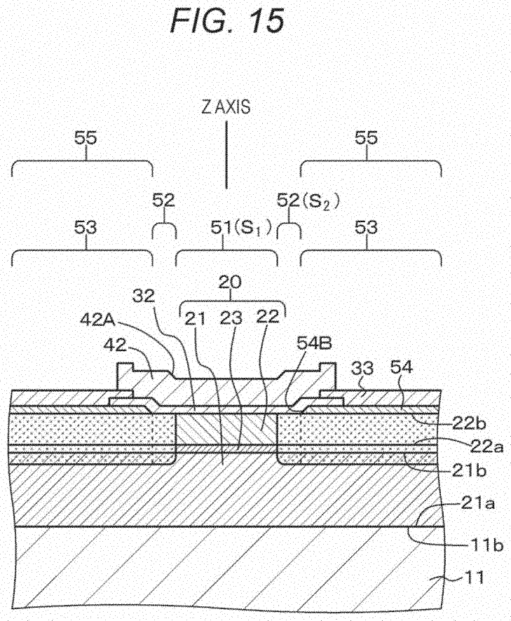

Example 8 is a modification of Examples 6 to 7, and relates to a light emitting element having the second configuration C. As illustrated in a schematic partial end view in FIG. 15, in the light emitting element of Example 8, the second light reflecting layer 42 includes a region that reflects or scatters light from the first light reflecting layer 41 toward the outside of the resonator structure including the first light reflecting layer 41 and the second light reflecting layer 42 (that is, toward the mode loss action region 55). Specifically, a portion of the second light reflecting layer 42 located above a side wall (side wall of the opening 54B) of the mode loss action site (mode loss action layer) 54 includes a forward tapered inclined portion 42A, or alternatively, includes a region convexly curved toward the first light reflecting layer 41.

In Example 8, the shape of the boundary between the current injection region 51 and the current non-injection/inner region 52 is circular (diameter: 8 μm), and the boundary between the current non-injection/inner region 52 and the current non-injection/outer region 53 is circular (diameter: 10 μm to 20 μm).

In Example 8, when the mode loss action site (mode loss action layer) 54 including the opening 54B and including SiO₂ is formed in a step similar to [Step-620] of Example 6, it is only required to form the opening 54B including a forward tapered side wall. Specifically, a resist layer is formed on the mode loss action layer formed on the second surface 22b of the second compound semiconductor layer 22, and an opening is provided on the basis of a photolithography technology on a portion of the resist layer to which the opening 54B is to be formed. On the basis of a well-known method, a side wall of the opening is made to have a forward tapered shape. Then, by performing etch back, the opening 54B including the forward tapered side wall can be formed at the mode loss action site (mode loss action layer) 54. Moreover, by forming the second electrode 32 and the second light reflecting layer 42 on such a mode loss action site (mode loss action layer) 54, the forward tapered inclined portion 42A can be given to the second light reflecting layer 42.

Except for the above points, the configuration and structure of the light emitting element of Example 8 can be similar to the configuration and structure of the light emitting element of Examples 6 to 7, and thus detailed description thereof will be omitted.

### Example 9

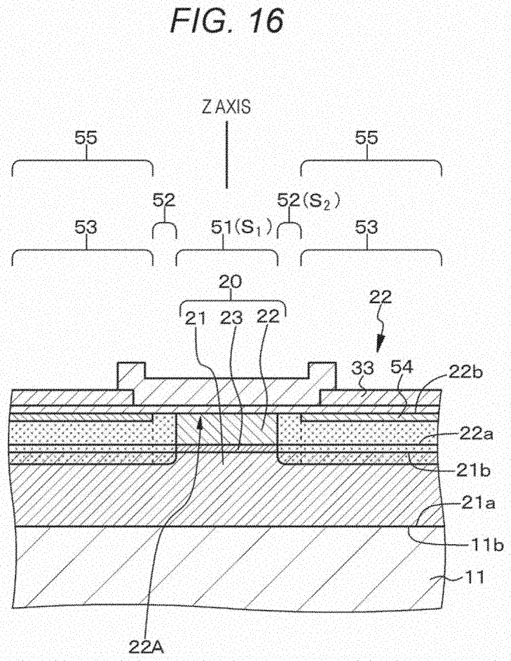

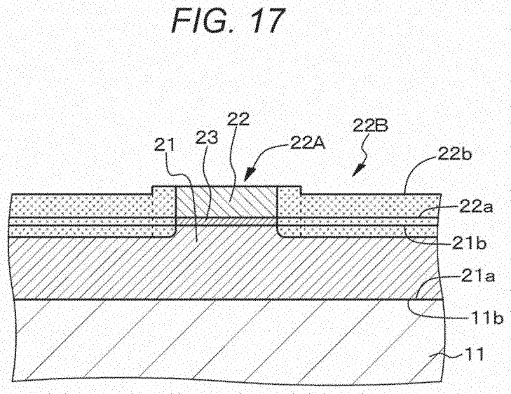

Example 9 is a modification of Examples 6 to 8 and relates to a light emitting element having the second configuration D. FIG. 16 illustrates a schematic partial end view of the light emitting element of Example 9, and as illustrated in a schematic partial end view in which the main part is cut out in FIG. 17, a protruding portion 22A is formed on the second surface 22b side of the second compound semiconductor layer 22. Then, as illustrated in FIGS. 16 and 17, the mode loss action site (mode loss action layer) 54 is formed on a region 22B of the second surface 22b of the second compound semiconductor layer 22 surrounding the protruding portion 22A. The protruding portion 22A occupies the current injection region 51, the current injection region 51, and the current non-injection/inner region 52. The mode loss action site (mode loss action layer) 54 includes a dielectric material, for example, SiO₂, similarly to Example 6. The region 22B is provided with the current non-injection/outer region 53. When the optical distance from the active layer 23 in the current injection region 51 to the second surface of the second compound semiconductor layer 22 is L₂, and the optical distance from the active layer 23 in the mode loss action region 55 to the top surface of the mode loss action site 54 (the surface facing the second electrode 32) is L₀,

L₀<L₂

is satisfied. Specifically,

L₂/L₀=1.5

is set. As a result, the lens effect is generated in the light emitting element.

In the light emitting element of Example 9, the generated laser beam having the higher-order mode is confined in the current injection region 51 and the current non-injection/inner region 52 by the mode loss action region 55, and thus the oscillation mode loss is reduced. That is, due to the presence of the mode loss action region 55 that acts on an increase or decrease of the oscillation mode loss, generated light field intensities of the basic mode and the higher-order mode increase in the orthographic projection images of the current injection region 51 and the current non-injection/inner region 52.

In Example 9, the shape of the boundary between the current injection region 51 and the current non-injection/inner region 52 is circular (diameter: 8 μm), and the boundary between the current non-injection/inner region 52 and the current non-injection/outer region 53 is circular (diameter: 30 μm).

In Example 9, it is only required to form the protruding portion 22A by removing a part of the second compound semiconductor layer 22 from the second surface 22b side between [Step-610] and [Step-620] of Example 6.

Except for the above points, the configuration and structure of the light emitting element of Example 9 can be similar to the configuration and structure of the light emitting element of Example 6, and thus detailed description thereof will be omitted. In the light emitting element of Example 9, it is possible not only to suppress the oscillation mode loss given by the mode loss action region for various modes and cause a transverse mode to oscillate in multiple modes, but also reduce a threshold value of laser oscillation. Furthermore, as illustrated in the conceptual diagram in (C) of FIG. 13, it is possible to increase the generated light field intensities of the basic mode and the higher-order mode in the orthographic projection images of the current injection region and the current non-injection/inner region by the presence of the mode loss action region that acts on an increase or decrease (specifically, decrease in Example 9) of the oscillation mode loss.

### Example 10

Example 10 is a modification of Examples 1 to 9, and relates to a light emitting element having the third configuration.

By the way, when the equivalent refractive index of the entire laminated structural body is n_{eq}, and the wavelength of the laser beam to be emitted from the surface emitting laser element (light emitting element) is λ₀, the resonator length L_{OR} in the laminated structural body including two DBR layers and a laminated structural body formed between them is represented by

L=(m·λ₀)/(2·n_{eq}).

Here, m is a positive integer. Then, in the surface emitting laser element (light emitting element), the wavelength at which oscillation is possible is determined by the resonator length L_{OR}. Individual oscillation modes capable of oscillation are referred to as longitudinal modes. Then, among the longitudinal modes, the one that matches a gain spectrum determined by the active layer can cause laser oscillation. When an effective refractive index is n_{eff}, a longitudinal mode interval Δλ is represented by

λ₀²/(2n_{eff}·L).

That is, the longer the resonator length L_{OR}, the narrower the longitudinal mode interval Δλ. Thus, in a case where the resonator length L_{OR} is long, a plurality of longitudinal modes can exist in the gain spectrum, so that a plurality of longitudinal modes can cause oscillation. Note that, when the oscillation wavelength is X₀, the equivalent refractive index n_{eq} and the effective refractive index n_{eff} have the following relationship.

n_{eff}=n_{eq}−λ₀·(dn_{eq}/d_{λ0})

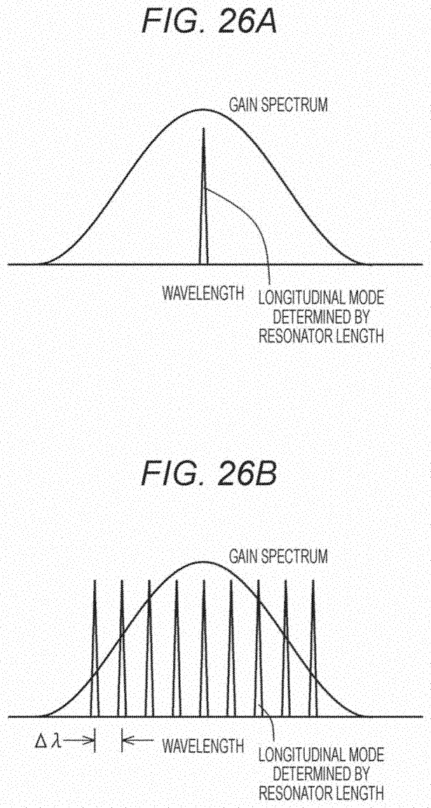

Here, in a case where the laminated structural body includes a GaAs-based compound semiconductor layer, the resonator length L_{OR} is usually as short as less than or equal to 1 μm, and there is one type (one wavelength) of longitudinal mode laser beam emitted from the surface emitting laser element (see the conceptual diagram in FIG. 26A). Thus, it is possible to accurately control the oscillation wavelength of the laser beam in the longitudinal mode emitted from the surface emitting laser element. On the other hand, in a case where the laminated structural body includes a GaN-based compound semiconductor layer, the resonator length L_{OR} is usually several times as long as the wavelength of the laser beam emitted from the surface emitting laser element. Thus, there is a plurality of types of longitudinal mode laser beams that can be emitted from the surface emitting laser element (see the conceptual diagram of FIG. 26B).

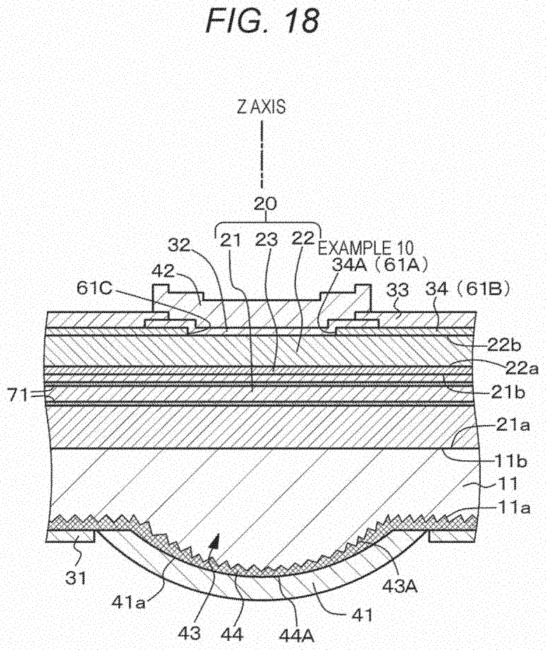

As illustrated in a schematic partial end view in FIG. 18, in the light emitting element of Example 10 or the light emitting elements of Examples 11 to 12 described later, at least two light absorbing material layers 71, preferably at least four light absorbing material layers 71, specifically in Example 10, twenty light absorbing material layers 71 are formed, in parallel with the virtual plane occupied by the active layer 23, in the laminated structural body 20 including the second electrode 32. Note that, to simplify the drawing, only two light absorbing material layers 71 are illustrated in the drawing.

In Example 10, the oscillation wavelength (desired oscillation wavelength emitted from the light emitting element) λ₀ is 450 nm. The twenty light absorbing material layers 71 include a compound semiconductor material having a narrower bandgap than the compound semiconductor constituting the laminated structural body 20, specifically, n-In_{0.2}Ga_{0.8}N, and is formed inside the first compound semiconductor layer 21. The thickness of the light absorbing material layer 71 is less than or equal to λ₀/(4·n_{eq}), specifically 3 nm. Furthermore, the light absorption coefficient of the light absorbing material layer 71 is more than twice, specifically, 1×10³ times, the light absorption coefficient of the first compound semiconductor layer 21 including the n-GaN layer.

Furthermore, the light absorbing material layer 71 is located in the minimum amplitude portion generated in the standing wave of light formed inside the laminated structural body, and the active layer 23 is located in the maximum amplitude portion generated in the standing wave of light formed inside the laminated structural body. A distance between the center in the thickness direction of the active layer 23 and the center in the thickness direction of the light absorbing material layer 71 adjacent to the active layer 23 is 46.5 nm. Moreover, when the overall equivalent refractive index of the two light absorbing material layers 71 and a portion of the laminated structural body located between the light absorbing material layer 71 and the light absorbing material layer 71 (specifically, in Example 10, the first compound semiconductor layer 21) is n_{eq}, and the distance between the light absorbing material layer 71 and the light absorbing material layer 71 is L_{Abs},

0.9×{(m·λ₀)/(2·n_{eq})}≤L_{Abs}≤1.1×{(m·λ₀)/(2·n_{eq})}

is satisfied. Here, m is 1 or any integer greater than or equal to 2 including 1. However, in Example 10, m=1 is set. Thus, in all the plurality of light absorbing material layers 71 (twenty light absorbing material layers 71), the distance between adjacent light absorbing material layers 71 satisfies

0.9×{λ₀/(2·n_{eq})}≤L_{Abs}≤1.1×{λ₀/(2·n_{eq})}.

The value of the equivalent refractive index n_{eq} is specifically 2.42, and when m=1, specifically,

$${L}_{Abs} = 1 \times 450 / ( 2 \times 2.42 ) = 93.0 nm .$$

Note that, among the twenty light absorbing material layers 71, in some of the light absorbing material layers 71, m can be set to any integer of greater than or equal to 2.

In manufacturing the light emitting element of Example 10, the laminated structural body 20 is formed in a step similar to [Step-100] of Example 1, and at this time, the twenty light absorbing material layers 71 are also formed inside the first compound semiconductor layer 21. Except for this point, the light emitting element of Example 10 can be manufactured on the basis of a method similar to that of the light emitting element of Example 1.

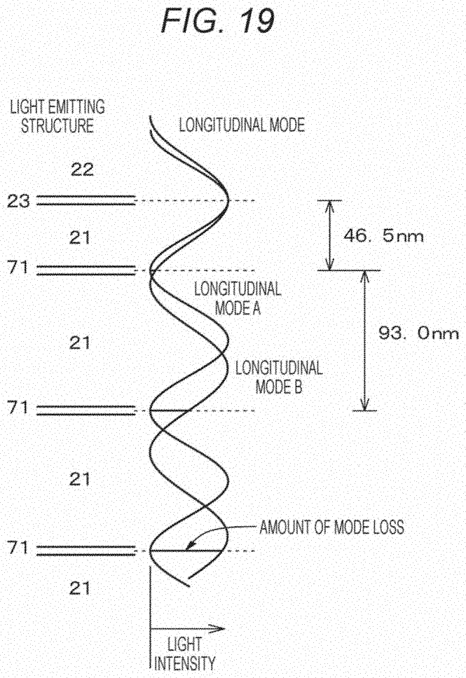

In a case where the plurality of longitudinal modes is generated in the gain spectrum determined by the active layer 23, this is schematically illustrated in FIG. 19. Note that, FIG. 19 illustrates two longitudinal modes, a longitudinal mode A and a longitudinal mode B. Then, in this case, it is assumed that the light absorbing material layer 71 is located in the minimum amplitude portion of the longitudinal mode A and is not located in the minimum amplitude portion of the longitudinal mode B. Then, the mode loss in the longitudinal mode A is minimized, but the mode loss in the longitudinal mode B is large. In FIG. 19, the mode loss of the longitudinal mode B is schematically illustrated by a solid line. Thus, the longitudinal mode A is easier to cause oscillation than the longitudinal mode B. Thus, by using such a structure, that is, by controlling a position and period of the light absorbing material layer 71, a specific longitudinal mode can be stabilized and oscillation can be facilitated. On the other hand, since the mode loss for other undesired longitudinal modes can be increased, it is possible to suppress oscillation of the other undesired longitudinal modes.

As described above, in the light emitting element of Example 10, since at least two light absorbing material layers are formed inside the laminated structural body, among the laser beams of a plurality of types of longitudinal modes that can be emitted from the surface emitting laser element, oscillation of the laser beam in the undesired longitudinal mode can be suppressed more effectively. As a result, it is possible to control the oscillation wavelength of the emitted laser beam more accurately. Moreover, even in the light emitting element of Example 10, since the protrusion is included, it is possible to reliably suppress the occurrence of the diffraction loss.

### Example 11

Example 11 is a modification of Example 10. In Example 10, the light absorbing material layer 71 includes a compound semiconductor material having a narrower bandgap than the compound semiconductor constituting the laminated structural body 20. On the other hand, in Example 11, ten light absorbing material layers 71 include a compound semiconductor material doped with impurities, specifically, a compound semiconductor material having an impurity concentration (impurity: Si) of 1×10¹⁹/cm′ (specifically, n-GaN: Si). Furthermore, in Example 11, the oscillation wavelength λ₀ is set to 515 nm. Note that, the composition of the active layer 23 is In_{0.3}Ga_{0.7}N. In Example 11, m=1 and the value of L_{Abs} is 107 nm, the distance between the center in the thickness direction of the active layer 23 and the center in the thickness direction of the light absorbing material layer 71 adjacent to the active layer 23 is 53.5 nm, and the thickness of the light absorbing material layer 71 is 3 nm. Except for the above points, the configuration and structure of the light emitting element of Example 11 can be similar to the configuration and structure of the light emitting element of Example 10, and thus detailed description thereof will be omitted. Note that, among the ten light absorbing material layers 71, in some of the light absorbing material layers 71, m can be set to any integer of greater than or equal to 2.

### Example 12

Example 12 is also a modification of Example 10. In Example 12, five light absorbing material layers (referred to as “first light absorbing material layer” for convenience) have a configuration similar to the light absorbing material layer 71 of Example 10, that is, n-In_{0.3}Ga_{0.7}N. Moreover, in Example 12, one light absorbing material layer (referred to as “second light absorbing material layer” for convenience) includes a transparent conductive material. Specifically, the second light absorbing material layer is also used as the second electrode 32 including ITO. In Example 12, the oscillation wavelength λ₀ is set to 450 nm. Furthermore, m=1 and 2 are set. In m=1, the value of L_{Abs} is 93.0 nm, a distance between the center in the thickness direction of the active layer 23 and the center in the thickness direction of the first light absorbing material layer adjacent to the active layer 23 is 46.5 nm, and the thickness of the five first light absorbing material layers is 3 nm. That is, in the five first light absorbing material layers,

0.9×{λ₀/(2·n_{eq})}≤L_{Abs}≤1.1×{λ₀/(2·n_{eq})}

is satisfied. Furthermore, in the first light absorbing material layer adjacent to the active layer 23 and the second light absorbing material layer, m=2 is set. That is,

0.9×{(2·λ₀)/(2·n_{eq})}≤L_{Abs}≤1.1×{(2·λ₀)/(2·n_{eq})}

is satisfied. The light absorption coefficient of one second light absorbing material layer that also serves as the second electrode 32 is 2000 cm′, the thickness is 30 nm, and a distance from the active layer 23 to the second light absorbing material layer is 139.5 nm. Except for the above points, the configuration and structure of the light emitting element of Example 12 can be similar to the configuration and structure of the light emitting element of Example 10, and thus detailed description thereof will be omitted. Note that, among the five first light absorbing material layers, in some of the first light absorbing material layers, m can be set to any integer of greater than or equal to 2. Note that, unlike Example 10, the number of the light absorbing material layers 71 can be set to one. In this case as well, a positional relationship between the second light absorbing material layer that also serves as the second electrode 32 and the light absorbing material layer 71 needs to satisfy the following expression.

0.9×{(m·λ₀)/(2·n_{eq})}≤L_{Abs}≤1.1×{(m·λ₀)/(2·n_{eq})}

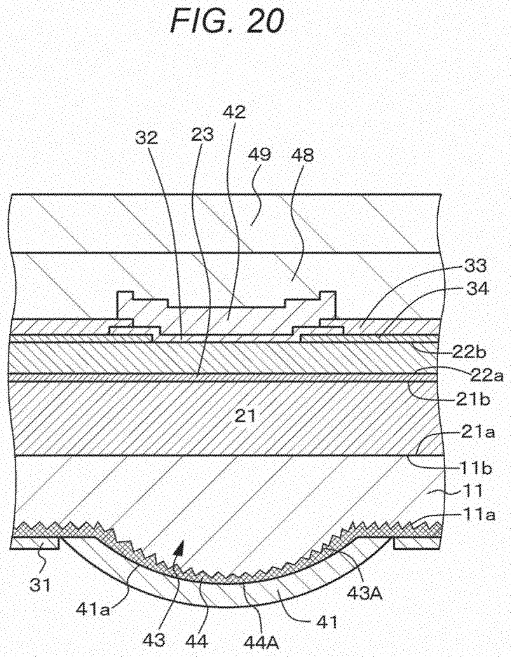

Although the present disclosure has been described above on the basis of preferable Examples, the present disclosure is not limited to these Examples. The configuration and structure of the light emitting element described in Examples are exemplification, and can be appropriately changed, and the method for manufacturing the light emitting element can also be appropriately changed. In some cases, the light emitting element can be a surface emitting laser element that emits light from the first compound semiconductor layer through the first light reflecting layer, and in this case, the second light reflecting layer may be supported by a support substrate 49 via a bonding layer 48 (see FIG. 20 that is a modification of the light emitting element of Example 1, and FIG. 21 that is a modification of the light emitting element of Example 2). Moreover, by appropriately selecting the bonding layer and the support substrate, the light emitting element can be a surface emitting laser element that emits light from the top surface of the second compound semiconductor layer through the second light reflecting layer.

Note that, the present disclosure can also adopt the following configurations.

### [A01]<<Light Emitting Element>>

A light emitting element including:

a laminated structural body in which a first compound semiconductor layer, an active layer, and a second compound semiconductor layer are laminated, the first compound semiconductor layer including a first surface and a second surface facing the first surface, the active layer facing the second surface of the first compound semiconductor layer, the second compound semiconductor layer including a first surface facing the active layer and a second surface facing the first surface;

a first electrode electrically connected to the first compound semiconductor layer; and

a second electrode and a second light reflecting layer formed on the second surface of the second compound semiconductor layer, in which

a protrusion is formed on the first surface's side of the first compound semiconductor layer,

a smoothing layer is formed on at least the protrusion,

the protrusion and the smoothing layer constitute a concave mirror portion,

a first light reflecting layer is formed on at least a part of the smoothing layer, and

the second light reflecting layer has a flat shape.

[A02] The light emitting element according to [A01], in which a value of a surface roughness Ra₁ of the smoothing layer at an interface between the smoothing layer and the first light reflecting layer is smaller than a value of a surface roughness Ra₂ of the protrusion at an interface between the protrusion and the smoothing layer.
[A03] The light emitting element according to [A02], in which the value of the surface roughness Ra₁ is less than or equal to 1.0 nm.
[A04] The light emitting element according to any one of [A01] to [A03], in which an average thickness of the smoothing layer at the top of the protrusion is thinner than an average thickness of the smoothing layer at an edge of the protrusion.
[A05] The light emitting element according to any one of [A01] to [A04], in which a radius of curvature of the smoothing layer is 1×10⁻⁵ m to 1×10⁻³ m.
[A06] The light emitting element according to any one of [A01] to[A05], in which a material constituting the smoothing layer is at least one material selected from a group consisting of a dielectric material, a spin-on-glass based material, a low melting point glass material, a semiconductor material, and a resin.

### [B01]<<Method for Manufacturing Light Emitting Element: First Aspect>>

A method for manufacturing a light emitting element, the method including steps of:

forming a laminated structural body in which a first compound semiconductor layer, an active layer, and a second compound semiconductor layer are laminated, the first compound semiconductor layer including a first surface and a second surface facing the first surface, the active layer facing the second surface of the first compound semiconductor layer, the second compound semiconductor layer including a first surface facing the active layer and a second surface facing the first surface; and then,

forming a second electrode and a second light reflecting layer on the second surface of the second compound semiconductor layer; and thereafter,

forming a protrusion on the first surface's side of the first compound semiconductor layer; and then,

forming a smoothing layer on at least the protrusion, and then smoothing a surface of the smoothing layer; and thereafter,

forming a first light reflecting layer on at least a part of the smoothing layer, and forming a first electrode electrically connected to the first compound semiconductor layer, in which

the protrusion and the smoothing layer constitute a concave mirror portion, and

the second light reflecting layer has a flat shape.

[B02] The method for manufacturing a light emitting element according to [B01], in which smoothing processing on the surface of the smoothing layer is based on a wet etching method.
[B03] The method for manufacturing a light emitting element according to [B01], in which smoothing processing on the surface of the smoothing layer is based on a dry etching method.
[B04] The method for manufacturing the light emitting element according to any one of [B01] to [B03], in which a value of a surface roughness Ra₁ of the smoothing layer at an interface between the smoothing layer and the first light reflecting layer is smaller than a value of a surface roughness Ra₂ of the protrusion at an interface between the protrusion and the smoothing layer.
[B05] The method for manufacturing a light emitting element according to [B04], in which the value of the surface roughness Ra₁ is less than or equal to 1.0 nm.
[B06] The method for manufacturing a light emitting element according to any one of [B01] to [B05], in which an average thickness of the smoothing layer at the top of the protrusion is thinner than an average thickness of the smoothing layer at an edge of the protrusion.
[B07] The method for manufacturing a light emitting element according to any one of [B01] to [B06], in which a radius of curvature of the smoothing layer is 1×10⁻⁵ m to 1×10⁻³ m.
[B08] The method for manufacturing a light emitting element according to any one of [B01] to [B07], in which a material constituting the smoothing layer is at least one material selected from a group consisting of a dielectric material, a spin-on-glass based material, a low melting point glass material, a semiconductor material, and a resin.

### [C01]<<Method for Manufacturing Light Emitting Element: Second Aspect>>

A method for manufacturing a light emitting element, the method including steps of:

forming a laminated structural body in which a first compound semiconductor layer, an active layer, and a second compound semiconductor layer are laminated, the first compound semiconductor layer including a first surface and a second surface facing the first surface, the active layer facing the second surface of the first compound semiconductor layer, the second compound semiconductor layer including a first surface facing the active layer and a second surface facing the first surface; and then

forming a second electrode and a second light reflecting layer on the second surface of the second compound semiconductor layer; and thereafter,

forming a protrusion on the first surface's side of the first compound semiconductor layer, and then smoothing a surface of the protrusion; and then,

forming a first light reflecting layer on at least a part of the protrusion, and forming a first electrode electrically connected to the first compound semiconductor layer, in which

the protrusion constitutes a concave mirror portion, and

the second light reflecting layer has a flat shape.

[C02] The method for manufacturing a light emitting element according to [C01], in which smoothing processing on the surface of the protrusion is based on a wet etching method.
[C03] The method for manufacturing a light emitting element according to [C01], in which smoothing processing on the surface of the protrusion is based on a dry etching method.

### [D01]<<Light Emitting Element Having First Configuration>>

The light emitting element according to any one of [A01] to [A06], in which

the second compound semiconductor layer is provided with a current injection region and a current non-injection region surrounding the current injection region, and

a shortest distance D_{CI} from an area center of gravity of the current injection region to a boundary between the current injection region and the current non-injection region satisfies an expression below.

D_{CI}≥ω₀/2

where

ω₀²≡(λ₀/π){L_{OR}(R_{DBR}−L_{OR})}^{1/2}

here,

λ₀: Wavelength of light mainly emitted from the light emitting element

L_{OR}: Resonator length

R_{DBR}: Radius of curvature of the inner surface of the first light reflecting layer

[D02] The light emitting element according to [D01], further including

a mode loss action site provided on the second surface of the second compound semiconductor layer and constituting a mode loss action region that acts on an increase or decrease in oscillation mode loss, and

a second electrode formed over the mode loss action site from the second surface of the second compound semiconductor layer, in which

in the laminated structural body, the current injection region, a current non-injection/inner region surrounding the current injection region, and a current non-injection/outer region surrounding the current non-injection/inner region are formed, and

an orthographic projection image of the mode loss action region and an orthographic projection image of the current non-injection/outer region overlap each other.

[D03] The light emitting element according to [D01] or [D02], in which

a radius r′_{DBR} of an effective region of the first light reflecting layer satisfies

ω₀≤r′_{DBR}≤20·ω₀.

[D04] The light emitting element according to any one of [D01] to [D03], in which D_{CI}≥ω₀ is satisfied.
[D05] The light emitting element according to any one of [D01] to [D04], in which R_{DBR}≤1×10⁻³ m is satisfied.

### [E01]<<Light Emitting Element Having Second Configuration>>

The light emitting element according to any one of [A01] to [A06], further including

a mode loss action site provided on the second surface of the second compound semiconductor layer and constituting a mode loss action region that acts on an increase or decrease in oscillation mode loss, and

a second electrode formed over the mode loss action site from the second surface of the second compound semiconductor layer, in which

in the laminated structural body, the current injection region, a current non-injection/inner region surrounding the current injection region, and a current non-injection/outer region surrounding the current non-injection/inner region are formed, and

an orthographic projection image of the mode loss action region and an orthographic projection image of the current non-injection/outer region overlap each other.

[E02] The light emitting element according to [E01], in which the current non-injection/outer region is located below the mode loss action region.
[E03] The light emitting element according to [E01] or [E02], in which when an area of a projection image in the current injection region is S₁ and an area of a projection image in the current non-injection/inner region is S₂,

0.01≤S₁/(S₁+S₂)≤0.7

is satisfied.

### [E04]<<Light Emitting Element Having Second Configuration A>>

The light emitting element according to any one of [E01] to [E03], in which the current non-injection/inner region and the current non-injection/outer region are formed by ion implantation into the laminated structural body.

[E05] The light emitting element according to [E04], in which an ion species is at least one ion selected from a group consisting of boron, proton, phosphorus, arsenic, carbon, nitrogen, fluorine, oxygen, germanium, and silicon.
[E06]<<Light Emitting Element Having Second Configuration B>> The light emitting element according to any one of [E01] to [E05], in which the current non-injection/inner region and the current non-injection/outer region are formed by plasma irradiation onto the second surface of the second compound semiconductor layer, ashing processing onto the second surface of the second compound semiconductor layer, or reactive ion etching processing onto the second surface of the second compound semiconductor layer.

### [E07]<<Light Emitting Element Having Second Configuration C>>

The light emitting element according to any one of [E01] to [E06], in which the second light reflecting layer includes a region that reflects or scatters light from the first light reflecting layer toward the outside of a resonator structure including the first light reflecting layer and the second light reflecting layer.

[E08] The light emitting element according to any one of [E04] to [E07], in which when an optical distance from the active layer in the current injection region to the second surface of the second compound semiconductor layer is L₂, and an optical distance from the active layer in the mode loss action region to the top surface of the mode loss action site is L₀,

L₀>L₂

is satisfied.

[E09] The light emitting element according to any one of [E04] to [E08], in which light having a higher-order mode generated is dissipated toward the outside of the resonator structure including the first light reflecting layer and the second light reflecting layer by the mode loss action region, and thus the oscillation mode loss is increased.
[E10] The light emitting element according to any one of [E04] to [E09], in which the mode loss action site can include a dielectric material, a metal material, or an alloy material.
[E11] The light emitting element according to [E10], in which the mode loss action site includes a dielectric material, and

an optical thickness of the mode loss action site has a value deviating from an integral multiple of ¼ of the wavelength of light generated in the light emitting element.

[E12] The light emitting element according to [E10], in which the mode loss action site includes a dielectric material, and

an optical thickness of the mode loss action site is an integral multiple of ¼ of the wavelength of light generated in the light emitting element.

[E13]<<Light Emitting Element with Second Configuration D>>

The light emitting element according to any one of [E01] to [E03], in which a protruding portion is formed on the second surface side of the second compound semiconductor layer, and

the mode loss action site is formed on a region of the second surface of the second compound semiconductor layer surrounding the protruding portion.

[E14] The light emitting element according to [E13], in which when the optical distance from the active layer in the current injection region to the second surface of the second compound semiconductor layer is L₂, and the optical distance from the active layer in the mode loss action region to the top surface of the mode loss action site is L₀,

L₀<L₂

is satisfied.

[E15] The light emitting element according to [E13] or [E14], in which light having the higher-order mode generated is confined in the current injection region and the current non-injection/inner region by the mode loss action region, and thus the oscillation mode loss is reduced.
[E16] The light emitting element according to any one of [E13] to [E15], in which the mode loss action site can include a dielectric material, a metal material, or an alloy material.
[E17] The light emitting element according to any one of [E01] to [E16], in which the second electrode includes a transparent conductive material.

### [F01]<<Light Emitting Element Having Third Configuration>>

The light emitting element according to any one of [A01] to [E17], in which at least two light absorbing material layers are formed in parallel with a virtual plane occupied by the active layer, in the laminated structural body including the second electrode.

[F02] The light emitting element according to [F01], in which at least four light absorbing material layers are formed.
[F03] The light emitting element according to [F01] or [F02], in which when the oscillation wavelength is λ₀, an overall equivalent refractive index of the two light absorbing material layers and a portion of the laminated structural body located between the light absorbing material layer and the light absorbing material layer is n_{eq}, and a distance between the light absorbing material layer and the light absorbing material layer is L_{Abs},

0.9×{(m·λ₀)/(2·n_{eq})}≤L_{Abs}≤1.1×{(m·λ₀)/(2·n_{eq})}

is satisfied. However, m is 1 or any integer greater than or equal to 2 including 1.

[F04] The light emitting element according to any one of [F01] to [F03], in which the thickness of the light absorbing material layer is less than or equal to λ₀/(4·n_{eq}).
[F05] The light emitting element according to any one of [F01] to [F04], in which the light absorbing material layer is located at a minimum amplitude portion generated in the standing wave of light formed inside the laminated structural body.
[F06] The light emitting element according to any one of [F01] to [F05], in which the active layer is located at a maximum amplitude portion generated in the standing wave of light formed inside the laminated structural body.
[F07] The light emitting element according to any one of [F01] to [F06], in which the light absorbing material layer has a light absorption coefficient of twice or more a light absorption coefficient of the compound semiconductor constituting the laminated structural body.
[F08] The light emitting element according to any one of [F01] to [F07], in which the light absorbing material layer includes at least one material selected from a group consisting of a compound semiconductor material having a narrower bandgap than the compound semiconductor constituting the laminated structural body, a compound semiconductor material doped with impurities, a transparent conductive material, and a light reflecting layer constituent material having light absorption characteristics.

### REFERENCE SIGNS LIST

11 Substrate
11a First surface of substrate
11b Second surface of substrate
20 Laminated structural body
21 First compound semiconductor layer
21a First surface of first compound semiconductor layer
21b Second surface of first compound semiconductor layer
22 Second compound semiconductor layer
22a First surface of second compound semiconductor layer
22b Second surface of second compound semiconductor layer
23 Active layer (light emitting layer)
31 First electrode
32 Second electrode
33 Pad electrode
34 Insulating layer (current constriction layer)
34A Opening provided in insulating layer (current constriction layer)
41 First light reflecting layer
41a Inner surface of first light reflecting layer
41b Effective region of first light reflecting layer
42 Second light reflecting layer
43, 45, 46, 47 Protrusion
44 Smoothing layer
48 Bonding layer
49 Support substrate
51 Current injection region
52 Current non-injection/inner region
53 Current non-injection/outer region
54 Mode loss action site (mode loss action layer)
54A, 54B Opening formed at mode loss action site
55 Mode loss action region
61A Current injection region
61B Current non-injection region
61C Boundary between current injection region and current non-injection region
71 Light absorbing material layer
81 Resist layer
82 Protrusion of resist layer

1. A light emitting element comprising:
a laminated structural body in which a first compound semiconductor layer, an active layer, and a second compound semiconductor layer are laminated, the first compound semiconductor layer including a first surface and a second surface facing the first surface, the active layer facing the second surface of the first compound semiconductor layer, the second compound semiconductor layer including a first surface facing the active layer and a second surface facing the first surface;
a first electrode electrically connected to the first compound semiconductor layer; and
a second electrode and a second light reflecting layer formed on the second surface of the second compound semiconductor layer, wherein
a protrusion is formed on the first surface's side of the first compound semiconductor layer,
a smoothing layer is formed on at least the protrusion,
the protrusion and the smoothing layer constitute a concave mirror portion,
a first light reflecting layer is formed on at least a part of the smoothing layer, and
the second light reflecting layer has a flat shape.

2. The light emitting element according to claim 1, wherein a value of a surface roughness Ra₁ of the smoothing layer at an interface between the smoothing layer and the first light reflecting layer is smaller than a value of a surface roughness Ra₂ of the protrusion at an interface between the protrusion and the smoothing layer.

3. The light emitting element according to claim 2, wherein the value of the surface roughness Ra₁ is less than or equal to 1.0 nm.

4. The light emitting element according to claim 1, wherein an average thickness of the smoothing layer at a top of the protrusion is thinner than an average thickness of the smoothing layer at an edge of the protrusion.

5. The light emitting element according to claim 1, wherein a radius of curvature of the smoothing layer is 1×10⁻⁵ m to 1×10⁻³ m.

6. The light emitting element according to claim 1, wherein a material constituting the smoothing layer is at least one material selected from a group consisting of a dielectric material, a spin-on-glass based material, a low melting point glass material, a semiconductor material, and a resin.

7. A method for manufacturing a light emitting element, the method comprising steps of:
forming a laminated structural body in which a first compound semiconductor layer, an active layer, and a second compound semiconductor layer are laminated, the first compound semiconductor layer including a first surface and a second surface facing the first surface, the active layer facing the second surface of the first compound semiconductor layer, the second compound semiconductor layer including a first surface facing the active layer and a second surface facing the first surface; and then,
forming a second electrode and a second light reflecting layer on the second surface of the second compound semiconductor layer; and thereafter,
forming a protrusion on the first surface's side of the first compound semiconductor layer; and then,
forming a smoothing layer on at least the protrusion, and then smoothing a surface of the smoothing layer; and thereafter,
forming a first light reflecting layer on at least a part of the smoothing layer, and forming a first electrode electrically connected to the first compound semiconductor layer, wherein
the protrusion and the smoothing layer constitute a concave mirror portion, and
the second light reflecting layer has a flat shape.

8. The method for manufacturing a light emitting element according to claim 7, wherein smoothing processing on the surface of the smoothing layer is based on a wet etching method.

9. The method for manufacturing a light emitting element according to claim 7, wherein smoothing processing on the surface of the smoothing layer is based on a dry etching method.

10. The method for manufacturing a light emitting element according to claim 7, wherein a value of a surface roughness Ra₁ of the smoothing layer at an interface between the smoothing layer and the first light reflecting layer is smaller than a value of a surface roughness Ra₂ of the protrusion at an interface between the protrusion and the smoothing layer.

11. The method for manufacturing a light emitting element according to claim 10, wherein the value of the surface roughness Ra₁ is less than or equal to 1.0 nm.

12. The method for manufacturing a light emitting element according to claim 7, wherein an average thickness of the smoothing layer at a top of the protrusion is thinner than an average thickness of the smoothing layer at an edge of the protrusion.

13. The method for manufacturing a light emitting element according to claim 7, wherein a radius of curvature of the smoothing layer is 1×10⁻⁵ m to 1×10⁻³ m.

14. The method for manufacturing a light emitting element according to claim 7, wherein a material constituting the smoothing layer is at least one material selected from a group consisting of a dielectric material, a spin-on-glass based material, a low melting point glass material, a semiconductor material, and a resin.

15. A method for manufacturing a light emitting element, the method comprising steps of:
forming a laminated structural body in which a first compound semiconductor layer, an active layer, and a second compound semiconductor layer are laminated, the first compound semiconductor layer including a first surface and a second surface facing the first surface, the active layer facing the second surface of the first compound semiconductor layer, the second compound semiconductor layer including a first surface facing the active layer and a second surface facing the first surface; and then
forming a second electrode and a second light reflecting layer on the second surface of the second compound semiconductor layer; and thereafter,
forming a protrusion on the first surface's side of the first compound semiconductor layer, and then smoothing a surface of the protrusion; and then,
forming a first light reflecting layer on at least a part of the protrusion, and forming a first electrode electrically connected to the first compound semiconductor layer, wherein
the protrusion constitutes a concave mirror portion, and
the second light reflecting layer has a flat shape.

16. The method for manufacturing a light emitting element according to claim 15, wherein smoothing processing on the surface of the protrusion is based on a wet etching method.

17. The method for manufacturing a light emitting element according to claim 15, wherein smoothing processing on the surface of the protrusion is based on a dry etching method.
